(19) United States
(12) Patent Application Publication
(10) Pub. No.: US 2025/0247056 A1
(43) Pub. Date: Jul. 31, 2025

(54) DETECTION CIRCUIT

(71) Applicant: Murata Manufacturing Co., Ltd., Kyoto (JP)

(72) Inventor: Shohei IMAI, Kyoto (JP)

(21) Appl. No.: 19/181,798

(22) Filed: Apr. 17, 2025

Related U.S. Application Data
(63) Continuation of application No. PCT/JP2023/037583, filed on Oct. 17, 2023.

(30) Foreign Application Priority Data
Oct. 18, 2022 (JP) 2022-166999
Sep. 25, 2023 (JP) 2023-160044

(51) Int. Cl. H03F 1/32; H03F 1/02; H03F 1/30; H03F 3/24; H03F 3/45

(52) U.S. Cl. CPC H03F 1/3211; H03F 1/0288; H03F 1/302; H03F 3/245; H03F 3/45085; H03F 2200/451

(57) ABSTRACT

A comparing unit that receives a signal output from an output terminal of a predetermined amplifier and a reference voltage and outputs, through an output terminal of the comparing unit, a first output signal corresponding to a difference between a signal level of the signal output from the predetermined amplifier and the reference voltage, a DC elimination unit whose first terminal is electrically connected to the output terminal of the comparing unit, a signal obtained by eliminating a DC component of the first output signal being output through a second terminal of the DC elimination unit, and a detection unit whose input terminal is electrically connected to the second terminal of the DC elimination unit, a control signal corresponding to the signal level of the signal output from the predetermined amplifier being output through an output terminal of the detection unit, are included.

### CROSS-REFERENCE TO RELATED APPLICATIONS

This application is a continuation of International Patent Application No. PCT/JP2023/037583 filed on Oct. 17, 2023, which claims priority to Japanese Patent Application No. 2022-166999 filed on Oct. 18, 2022 and Japanese Patent Application No. 2023-160044 filed on Sep. 25, 2023. These applications are herein incorporated by reference in their entireties.

### BACKGROUND ART

### Technical Field

The present disclosure relates to a detection circuit.

For example, it is known that in a power amplifier circuit, such as a Doherty amplifier circuit, including a plurality of power amplifiers, in order to improve efficiency, a circuit that detects saturation of a power amplifier is provided (Patent Document 1).
Patent Document 1: U.S. Patent Application Publication No. 2020/28472

### BRIEF SUMMARY

In Patent Document 1, a power amplifier circuit including a saturation detection circuit that detects saturation of a power amplifier is disclosed. In the saturation detection circuit described in Patent Document 1, an input terminal of a comparator for detecting saturation of the power amplifier is electrically connected to an output terminal of the power amplifier. An output of the comparator of the saturation detection circuit serves as a direct output of the saturation detection circuit. The saturation detection circuit outputs a DC detection signal by smoothing the sum of collector voltages of two transistors whose emitters are each electrically connected to the power amplifier with a resistor interposed therebetween and whose collectors are each electrically connected to a terminal for detecting saturation. At this time, the saturation detection circuit outputs a detection signal of a DC voltage that is made stable by a self-bias effect due to the resistor connected to the emitters of the transistors. However, in the saturation detection circuit, it takes time for the DC voltage to be made stable by operation of the transistors. Therefore, the length of time until saturation is detected increases. As described above, since response from the comparator itself is delayed due to a DC component directly output from the comparator, the saturation detection circuit has a problem in which a delay occurs in detection of the signal level of the power amplifier.

The present disclosure provides a detection circuit that quickly detects saturation of a power amplifier.

A detection circuit according to an aspect of the present disclosure includes a comparing unit that receives a signal output from an output terminal of a predetermined amplifier and a reference voltage and outputs, through an output terminal of the comparing unit, a first output signal corresponding to a difference between a signal level of the signal output from the predetermined amplifier and the reference voltage; a DC elimination unit whose first terminal is electrically connected to the output terminal of the comparing unit, a signal obtained by eliminating a DC component of the first output signal being output through a second terminal of the DC elimination unit; and a detection unit whose input terminal is electrically connected to the second terminal of the DC elimination unit, a control signal corresponding to the signal level of the signal output from the predetermined amplifier being output through an output terminal of the detection unit.

According to the present disclosure, a detection circuit that quickly detects saturation of a power amplifier can be provided.

### BRIEF DESCRIPTION OF THE DRAWINGS

FIG. 1 is a diagram illustrating an example of the configuration of a power amplifier module.

FIG. 2 is a diagram illustrating a configuration of a power amplifier module according to a first modification.

FIG. 3 is a diagram illustrating a configuration of a power amplifier module according to a second modification.

FIG. 4 is a diagram illustrating a configuration of a power amplifier module according to a third modification.

FIG. 5 is a diagram illustrating a configuration of a power amplifier module according to a fourth modification.

FIG. 6 is a diagram illustrating a configuration of a power amplifier module according to a fifth modification.

FIG. 7 is a diagram illustrating an example of the configuration of a detection circuit.

FIG. 8 is a diagram illustrating a specific example of the configuration of the detection circuit.

FIG. 9 is a diagram illustrating an example of the configuration of a detection circuit according to a first modification.

FIG. 10 is a diagram illustrating another example of the configuration of the detection circuit according to the first modification.

FIG. 11 is a diagram illustrating a configuration of a detection circuit according to a second modification.

FIG. 12 is a diagram illustrating a configuration of a detection circuit according to a third modification.

FIG. 13 is a diagram illustrating a specific example of the configuration of the detection circuit according to the third modification.

FIG. 14 is a diagram illustrating an example of the configuration of a detection circuit according to a fourth modification.

FIG. 15 is a diagram illustrating another example of the configuration of the detection circuit according to the fourth modification.

FIG. 16 explains a configuration of a detection circuit according to a fifth modification.

FIG. 17 is a diagram illustrating a configuration of a detection circuit according to a sixth modification.

FIG. 18 is a diagram illustrating a configuration of a detection circuit according to a seventh modification.

FIG. 19 is a plan view illustrating the arrangement of component elements of a power amplifier module.

FIG. 20 is a diagram illustrating a configuration of a detection circuit according to an eighth modification.

FIG. 21 is a diagram illustrating a specific example of the configuration of the detection circuit according to the eighth modification.

FIG. 22 is a diagram illustrating an example of the arrangement of the detection circuit according to the eighth modification at a substrate.

FIGS. 23A to 23C include diagrams illustrating a specific example of the configuration of a detection circuit according to a ninth modification.

FIG. 24 is a diagram illustrating a configuration of a power amplifier module according to another modification.

### DETAILED DESCRIPTION

Embodiments of the present disclosure will be described below with reference to drawings. Circuit elements with the same signs represent the same circuit elements and redundant description will be omitted.

### ===Configuration of Power Amplifier Module 1000===

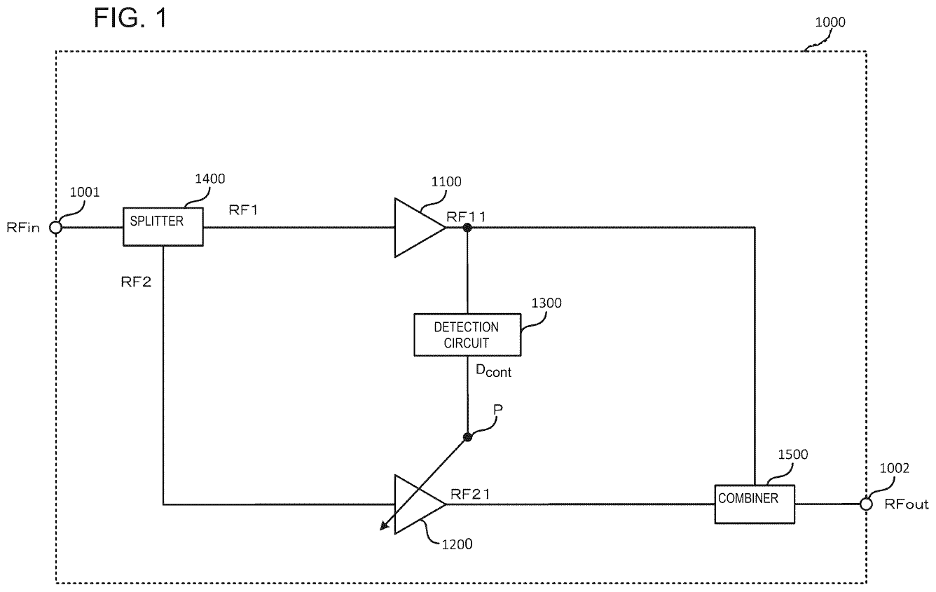

A configuration of a power amplifier module according to a first embodiment will be described with reference to FIG. 1. FIG. 1 is a diagram illustrating an example of the configuration of a power amplifier module 1000.

For example, the power amplifier module 1000 is mounted on a mobile phone and is used to amplify electric power of a signal to be transmitted to a base station. The power amplifier module 1000 is capable of amplifying electric power of signals based on, for example, communication standards, such as 2G (second generation mobile communication system), 3G (third generation mobile communication system), 4G (fourth generation mobile communication system), 5G (fifth generation mobile communication system), LTE (Long Term Evolution)-FDD (Frequency Division Duplex), LTE-TDD (Time Division Duplex), LTE-Advanced, LTE-Advanced Pro, and the like. Communication standards for signals amplified by the power amplifier module 1000 are not limited to those mentioned above.

As illustrated in FIG. 1, for example, the power amplifier module 1000 amplifies an input signal RFin input through an input terminal 1001 and outputs an output signal RFout through an output terminal 1002. The input signal RFin is a wireless frequency (RF: Radio-Frequency) signal. The frequency of the input signal RFin is, for example, on the order of several GHz.

The power amplifier module 1000 includes, for example, a carrier amplifier 1100, a peak amplifier 1200, a detection circuit 1300, a splitter 1400, and a combiner 1500. As illustrated in FIG. 1, the power amplifier module 1000 configures a Doherty amplifier circuit.

In a typical Doherty amplifier circuit, the carrier amplifier 1100 that operates irrespective of the power level of an input signal and the peak amplifier 1200 that is turned off when the power level of an input signal is small and turned on when the power level of an input signal is large are connected in parallel. In the Doherty amplifier circuit, the peak amplifier 1200 is caused to operate at the timing when the carrier amplifier 1100 approaches saturation. Thus, compared to normal power amplifier circuits, efficiency can be improved in the Doherty amplifier circuit.

In the power amplifier module 1000, by causing the detection circuit 1300, which will be described later, to properly detect the saturation state of the carrier amplifier 1100, the peak amplifier 1200 can be caused to operate at an appropriate timing.

The carrier amplifier 1100 is, for example, an amplifier that amplifies a signal RF1 output from the splitter 1400 and outputs a signal RF11. The carrier amplifier 1100 is biased to, for example, class A, class AB, or class B. That is, the carrier amplifier 1100 amplifies an input signal, irrespective of the power level of the input signal, such as a small instantaneous input power, and outputs the amplified signal.

The peak amplifier 1200 is, for example, an amplifier that amplifies a signal RF2 output from the splitter 1400 and outputs a signal RF21. The peak amplifier 1200 is biased to, for example, class A, class AB, class B, or class C.

The detection circuit 1300 is a circuit that detects the signal level of the signal RF1 output from the carrier amplifier 1100. A signal level is, for example, a voltage. For example, the detection circuit 1300 outputs a signal indicating a signal level (hereinafter, referred to as a “control signal D_{cont}”) to a terminal P of the peak amplifier 1200. The gain of the peak amplifier 1200 increases as the control signal D_{cont} increases.

As described above, the power amplifier module 1000 is capable of causing the peak amplifier 1200 to operate at an appropriate timing when the carrier amplifier 1100 saturates or starts to saturate.

The detection circuit 1300 does not necessarily output the control signal D_{cont} to the peak amplifier 1200. For example, the detection circuit 1300 may output the control signal D_{cont} to a bias circuit (not illustrated in the drawing) for the peak amplifier 1200. In this case, the detection circuit 1300 controls a bias point of the peak amplifier 1200 on the basis of the control signal D_{cont}.

For example, the splitter 1400 splits the signal RFin into the signal RF1 to be input to the carrier amplifier 1100 and the signal RF2 to be input to the peak amplifier 1200. For example, the phase of the signal RF2 is delayed by approximately 90 degrees with respect to the phase of the signal RF1. The splitter 1400 may be, for example, a distributed constant circuit such as a coupled-line 3 dB coupler or a Wilkinson splitter. The expression “approximately 90 degrees” includes, for example, a range from 45 degrees to 135 degrees.

For example, the combiner 1500 combines the signal RF11 output from the carrier amplifier 1100 and input through a phase shifter (not illustrated in the drawing) and the signal RF21 output from the peak amplifier 1200 and outputs an amplification signal Pout.

### <<Modification>>

As described above with reference to FIG. 1, the power amplifier module 1000 includes the carrier amplifier 1100 and the peak amplifier 1200, and the detection circuit 1300 outputs the control signal D_{cont} to the peak amplifier 1200. However, the present disclosure is not limited to this configuration.

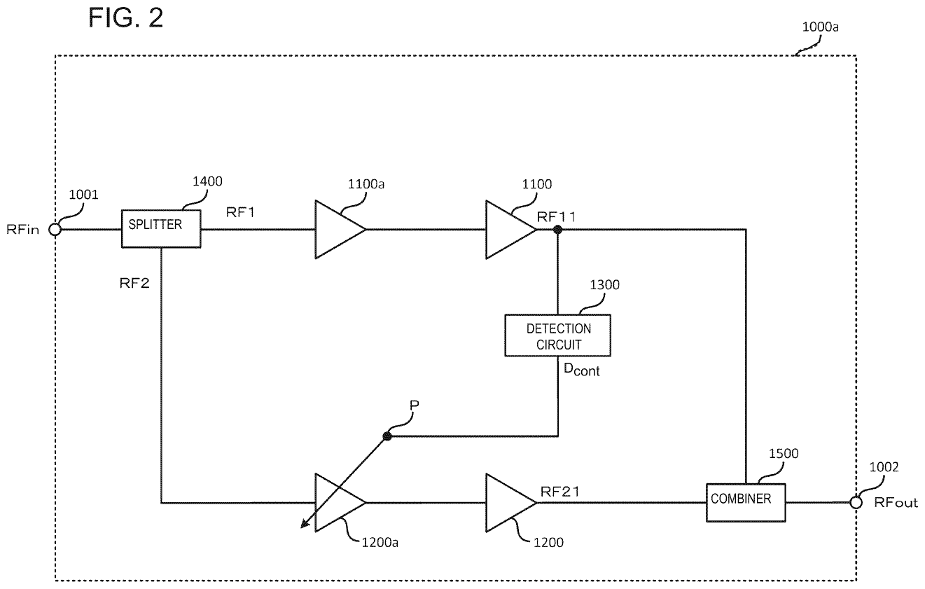

Modifications of the configuration of the power amplifier module 1000 will be described below with reference to FIGS. 2 to 6. FIGS. 2 to 6 are diagrams illustrating configurations of the power amplifier module 1000 according to the modifications. Only configuration features different from those of the power amplifier module 1000 will be described below.

As illustrated in FIG. 2, a power amplifier module 1000a according to a first modification further includes a drive-stage carrier amplifier 1100a connected in series to the carrier amplifier 1100 and a drive-stage peak amplifier 1200a connected in series to the peak amplifier 1200. In this case, for example, the detection circuit 1300 detects the signal level of the signal RF11 output from the carrier amplifier 1100 in the final stage and outputs the control signal D_{cont} to the drive-stage peak amplifier 1200a.

Accordingly, the power amplifier module 1000a is capable of causing the peak amplifier 1200a and the peak amplifier 1200 to operate at the appropriate timing when the carrier amplifier 1100 saturates or starts to saturate.

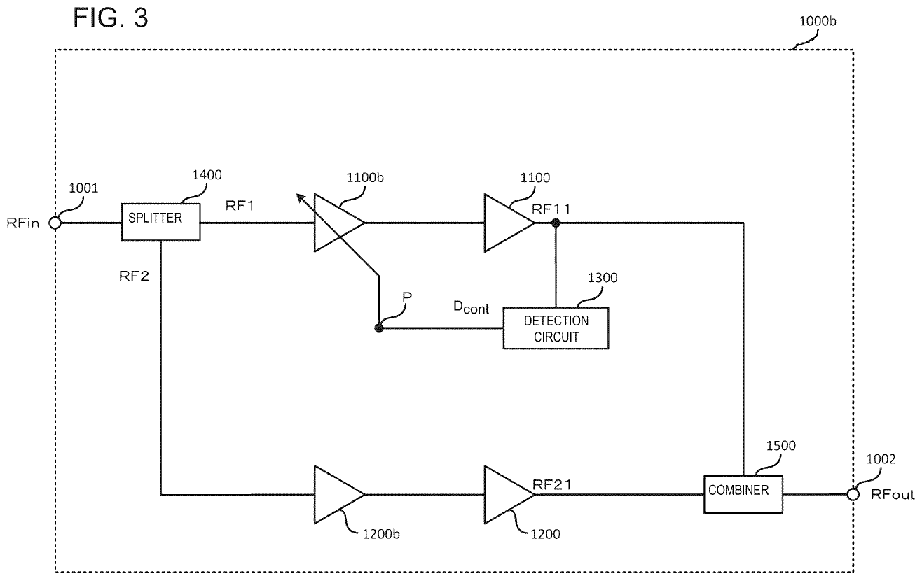

As illustrated in FIG. 3, a power amplifier module 1000b according to a second modification further includes a drive-stage carrier amplifier 1100b connected in series to the carrier amplifier 1100. In this case, for example, the detection circuit 1300 detects the signal level of the signal RF11 output from the carrier amplifier 1100 in the final stage and outputs the control signal D_{cont} to the drive-stage carrier amplifier 1100b.

Accordingly, the power amplifier module 1000b is capable of properly controlling the operation of the carrier amplifier 1100b at the appropriate timing when the carrier amplifier 1100 saturates or starts to saturate.

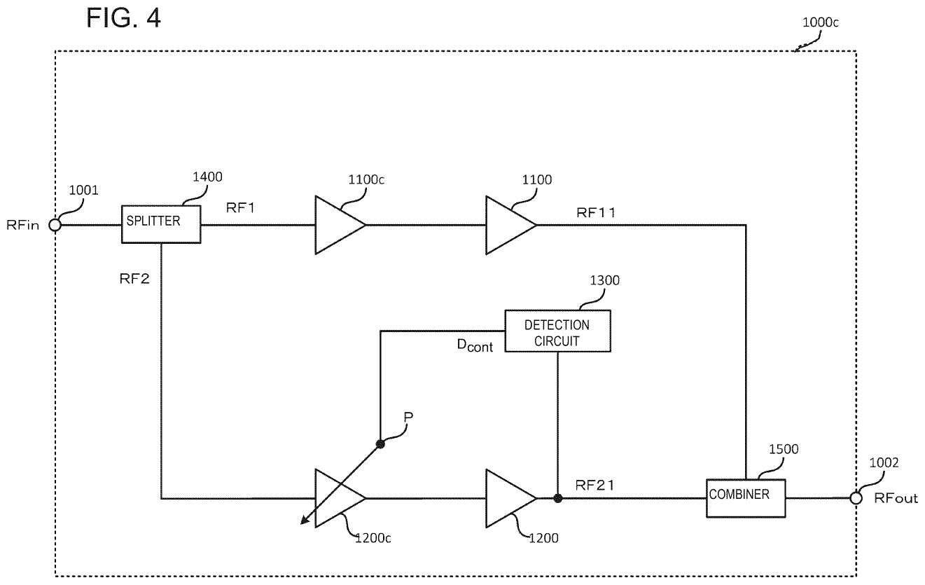

As illustrated in FIG. 4, a power amplifier module 1000c according to a third modification further includes a drive-stage peak amplifier 1200c connected in series to the peak amplifier 1200. In this case, for example, the detection circuit 1300 detects the signal level of the signal RF21 output from the peak amplifier 1200 in the final stage and outputs the control signal D_{cont} to the drive-stage peak amplifier 1200c.

Accordingly, the power amplifier module 1000c is capable of properly controlling the operation of the peak amplifier 1200c at the appropriate timing when the peak amplifier 1200 saturates or starts to saturate.

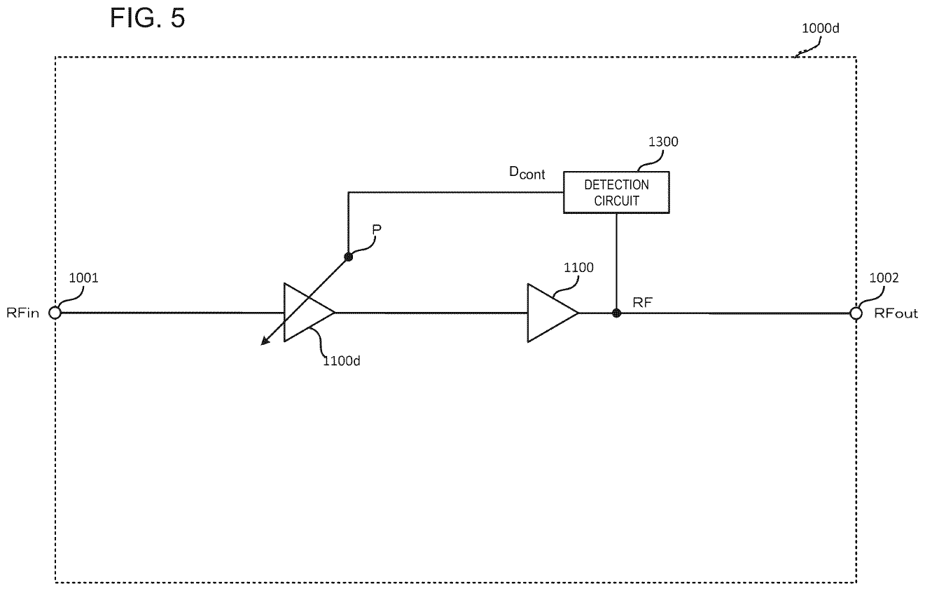

As illustrated in FIG. 5, a power amplifier module 1000d according to a fourth modification does not include a Doherty amplifier circuit but includes the final-stage amplifier 1100 and a drive-stage amplifier 1100d. In this case, for example, the detection circuit 1300 detects the signal level of a signal RF output from the final-stage amplifier 1100 and outputs the control signal D_{cont} to the drive-stage amplifier 1100d.

Accordingly, the power amplifier module 1000d is capable of properly controlling the operation of the drive-stage amplifier 1100d at the appropriate timing when the final-stage amplifier 1100 saturates or starts to saturate.

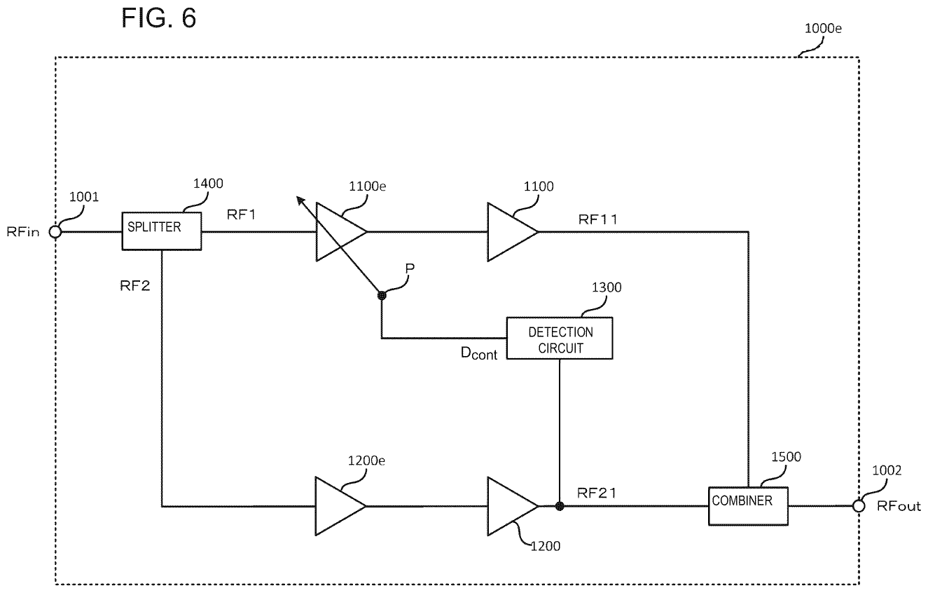

As illustrated in FIG. 6, a power amplifier module 1000e according to a fifth modification further includes a drive-stage carrier amplifier 1100e connected in series to the carrier amplifier 1100. In this case, for example, the detection circuit 1300 detects the signal level of the signal RF21 output from the peak amplifier 1200 in the final stage and outputs the control signal D_{cont} to the drive-stage carrier amplifier 1100e.

Accordingly, the power amplifier module 1000e is capable of properly controlling the operation of the carrier amplifier 1100e at the appropriate timing when the peak amplifier 1200 saturates or starts to saturate.

### ===Configuration of Detection Circuit 1300===

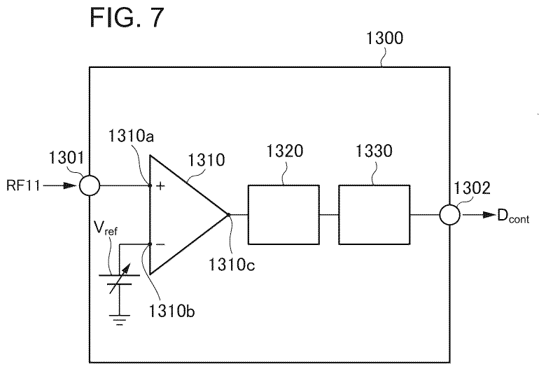

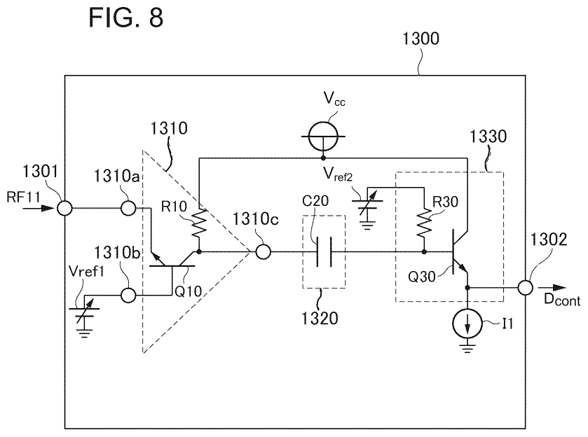

Next, a configuration of the detection circuit 1300 will be specifically described with reference to FIGS. 7 and 8. FIG. 7 is a diagram illustrating an example of the configuration of the detection circuit 1300. FIG. 8 is a diagram illustrating a specific example of the configuration of the detection circuit 1300.

For example, description will be provided based on a configuration (Doherty amplifier circuit) of the power amplifier module 1000.

Furthermore, for example, transistors will be described below as bipolar transistors. The transistors may be FETs (Field Effect Transistors). In this case, the emitter, the collector, and the base of a bipolar transistor may be regarded as the source, the drain, and the gate of an FET.

The overview of the configuration of the detection circuit 1300 will be described with reference to FIG. 7. As illustrated in FIG. 7, the detection circuit 1300 includes an input terminal 1301 that is electrically connected to an output terminal of the carrier amplifier 1100 and a detection terminal 1302 for detecting the signal level of an output from the carrier amplifier 1100.

The detection circuit 1300 includes, for example, the input terminal 1301, the detection terminal 1302, a comparing unit 1310, a DC elimination unit 1320, and a detection unit 1330.

The input terminal 1301 is, for example, a terminal that is electrically connected to the output terminal of the carrier amplifier 1100.

The detection terminal 1302 is, for example, a terminal that is electrically connected to the terminal P of the peak amplifier 1200. That is, the detection terminal 1302 is a terminal for detecting the signal level of an output from the carrier amplifier 1100.

For example, the comparing unit 1310 is a comparator and outputs, based on, as a boundary, a reference voltage input to one input terminal, an output signal corresponding to a voltage input to another input terminal.

Specifically, the comparing unit 1310 includes, for example, two input terminals 1310a and 1310b and an output terminal 1310c. In the comparing unit 1310, the first input terminal 1310a is electrically connected to the output terminal of the carrier amplifier 1100 and the second input terminal 1310b is electrically connected to a reference voltage Vref. The output terminal 1310c of the comparing unit 1310 is electrically connected to the DC elimination unit 1320, which will be described later.

The DC elimination unit 1320 eliminates a DC component of an output signal output from the comparing unit 1310. That is, the DC elimination unit 1320 allows a high frequency component of the output signal to pass therethrough.

For example, a first terminal of the DC elimination unit 1320 is electrically connected to the output terminal 1310c of the comparing unit 1310 and a second terminal of the DC elimination unit 1320 is electrically connected to the detection unit 1330, which will be described later.

The detection unit 1330 detects an output signal obtained by eliminating a DC component by the DC elimination unit 1320. At this time, the detection unit 1330 converts the output signal into a DC component and outputs the control signal D_{cont}.

For example, an input terminal of the detection unit 1330 is electrically connected to the second terminal of the DC elimination unit 1320 and an output terminal of the detection unit 1330 is electrically connected to the detection terminal 1302.

As described above, by eliminating a DC component of an output signal output from the comparing unit 1310, the detection circuit 1300 can prevent the delay in the response time of the comparing unit 1310 due to the DC component. Furthermore, by eliminating a DC component of an output signal output from the comparing unit 1310, the detection circuit 1300 can also reduce variations in a bias point of the detection unit 1330.

In contrast, in the saturation detection circuit according to Patent Document 1, it takes a long time to make a DC component of an output signal output from the comparator stable. In other words, in the saturation detection circuit, since a DC component output from the comparator affects the operation of the comparator itself, it takes a long time until a response becomes stable.

That is, in the case of the detection circuit 1300, with the configuration to eliminate a DC component of an output signal from the comparing unit 1310, the output signal does not affect the operation of the comparing unit 1310. Thus, the detection circuit 1300 can achieve a remarkable effect, such as being able to reduce the delay in the response time of the comparing unit 1310, compared to related art.

Next, an example of a specific configuration of the detection circuit 1300 will be described with reference to FIG. 8.

As illustrated in FIG. 8, the comparing unit 1310 includes, for example, a transistor Q10. For example, the emitter of transistor Q10 is electrically connected to the output terminal (for example, collector) of the carrier amplifier 1100, the base of the transistor Q10 is electrically connected to a reference voltage V_{ref1}, and the collector of the transistor Q10 is electrically connected to the first terminal of the DC elimination unit 1320. The collector of the transistor Q10 is electrically connected to a power source V_{cc} with a resistor R10 interposed therebetween.

The DC elimination unit 1320 eliminates a DC component, which requires time to become stable due to the influence of the operation of the comparing unit 1310 (operation of the transistor Q10), output from the comparing unit 1310. The DC elimination unit 1320 outputs a high frequency component to be used as a detection signal to the detection unit 1330. That is, in order that the DC component that requires time to become stable does not affect the detection unit 1330, the DC elimination unit 1320 isolates the comparing unit 1310 from the detection unit 1330 in a DC manner. As described above, the detection circuit 1300 eliminates the DC component that requires time to become stable and uses a high frequency component as a detection signal. Accordingly, a delay in a response that occurs in the case where a DC component output from the comparing unit 1310 is used as a detection signal, can be removed.

The DC elimination unit 1320 includes, for example, a capacitor C20. A first terminal of the capacitor C20 is electrically connected to the collector of the transistor Q10, and a second terminal of the capacitor C20 is electrically connected to the detection unit 1330.

The detection unit 1330 includes, for example, a transistor Q30. The transistor Q30 is, for example, an emitter follower. The conduction angle of the transistor Q30 is adjusted based on a reference voltage V_{ref2}, and a high frequency component of a signal output from the DC elimination unit 1320 is smoothed into DC using a capacitor, which is not illustrated in the drawing.

The base of the transistor Q30 is electrically connected to the second terminal of the capacitor C20 of the DC elimination unit 1320, the collector of the transistor Q30 is electrically connected to the power source V_{cc}, and the emitter of the transistor Q30 is electrically connected to the detection terminal 1302. Furthermore, for example, the base of the transistor Q30 is electrically connected to the reference voltage V_{ref2} with a resistor R30 interposed therebetween, and the emitter of the transistor Q30 is electrically connected to a constant current source I1.

Next, the overview of an operation of the detection circuit 1300 will be described.

The collector of the carrier amplifier 1100 whose emitter is grounded is electrically connected to the detection circuit 1300. In this case, the instantaneous minimum voltage of the collector of the carrier amplifier 1100 decreases (approaches 0 V) as the carrier amplifier 1100 approaches saturation. That is, the detection circuit 1300 enters a conduction state during a period in which the voltage (signal level) of the input signal RF11 input to the input terminal 1301 is lower than the reference voltage V_{ref1}.

A condition state period expressed as an angle range is called a conduction angle. The conduction angle increases as the input signal RF11 increases. A DC component of an output signal output from the comparing unit 1310 increases as the conduction angle increases. In the detection circuit 1300, the DC component is eliminated by the DC elimination unit 1320.

In the detection circuit 1300, the detection unit 1330 as an emitter follower is used. Thus, in the detection unit 1330, the input impedance is high, and only a small input current is thus required. Since the input impedance of the detection unit 1330 is high, the input signal RF11 functions to operate the emitter follower but does not directly affect the DC component of the control signal D_{cont}. That is, in the detection circuit 1300, with the use of the detection unit 1330 as an emitter follower, interaction between the comparing unit 1310 and the detection unit 1330 in an AC manner can be suppressed (AC input impedance is increased).

Accordingly, even if the AC output impedance of the comparing unit 1310 is high, interaction with the detection unit 1330 in an AC manner can be suppressed. For example, in the case where the AC output impedance of the comparing unit 1310 is high and the AC input impedance of the detection unit 1330 is low, when the detection unit 1330 starts to operate, the input impedance of the comparing unit 1310 normally decreases. That is, although an AC output from the comparing unit 1310 is normally unstable, by using an emitter follower as the detection unit 1330 in the detection circuit 1300 to increase the input impedance, the AC output from the comparing unit 1310 can be made stable.

As described above with reference to FIG. 8, the comparing unit 1310 includes a transistor whose base is grounded. However, the comparing unit 1310 does not necessarily include the transistor described above. For example, the comparing unit 1310 may include a transistor whose emitter is grounded. That is, the comparing unit 1310 may be a comparator that compares between the voltage of the collector and the voltage of the base of the transistor.

Specifically, when the potential of the collector is lower than the potential of the base by the base-emitter voltage V_{be} or more, the comparing unit 1310 executes a function of the comparator by using a phenomenon in which the base current increases. That is, the comparing unit 1310 may be configured to bias the base of the transistor to the base-emitter voltage V_{be} and cause the base current to flow when the potential of the collector approaches “0”.

In this case, in the comparing unit 1310, the emitter of the transistor is electrically connected to the ground, the collector of the transistor is electrically connected to the collector (output terminal) of the carrier amplifier 1100, and the base of the transistor is electrically connected to the reference voltage V_{ref1} and electrically connected to the first terminal of the DC elimination unit 1320.

As described above, with the use of the transistor whose emitter is grounded in the comparing unit 1310, a breakdown of the transistor can be suppressed compared to the case where a transistor whose base is grounded is used. This is because, whereas a large voltage is applied between the base and emitter of a transistor whose base is grounded, a large voltage is not applied between the base and emitter of a transistor whose emitter is grounded.

### <<First Modification>>

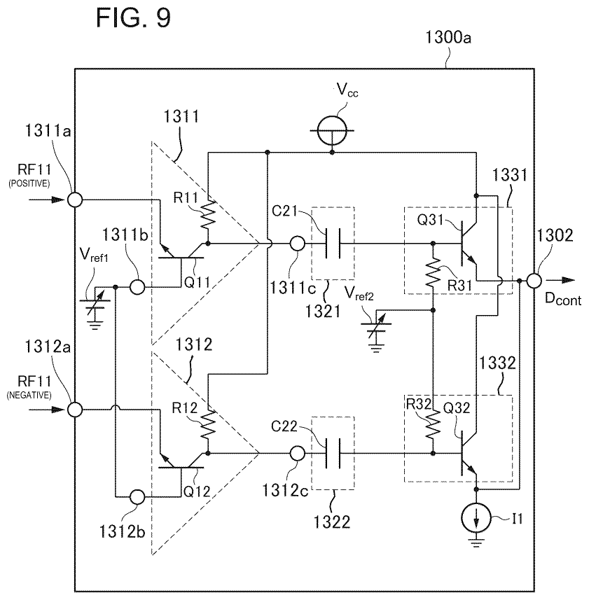

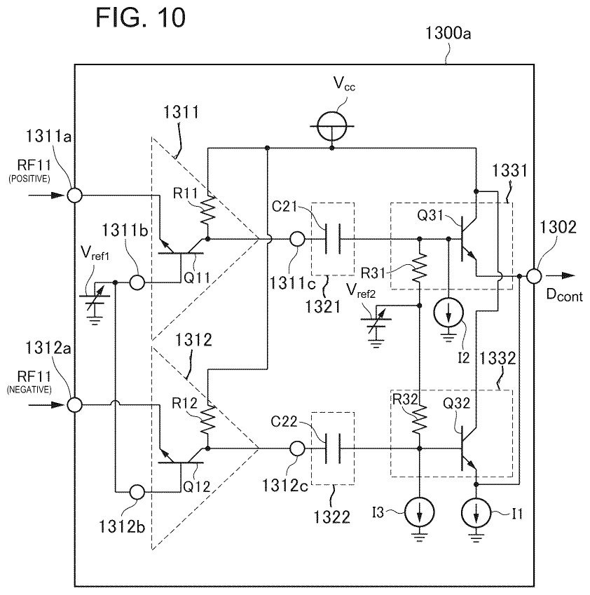

A configuration of a detection circuit 1300a according to the first modification will be described with reference to FIGS. 9 and 10. FIG. 9 is a diagram illustrating an example of the configuration of the detection circuit 1300a according to the first modification. FIG. 10 is a diagram illustrating another example of the configuration of the detection circuit 1300a according to the first modification.

The detection circuit 1300a is obtained by configuring the detection circuit 1300 as a differential circuit. That is, for example, the detection circuit 1300a is used for the case where the carrier amplifier 1100 includes a differential circuit. In the description provided below, the carrier amplifier 1100 includes a positive-side carrier amplifier (not illustrated in the drawing) and a negative-side carrier amplifier (not illustrated in the drawing).

As illustrated in FIG. 9, the detection circuit 1300a includes a comparing part 1311 and a comparing part 1312 that correspond to the comparing unit 1310, a DC elimination part 1321 and a DC elimination part 1322 that correspond to the DC elimination unit 1320, and a detection part 1331 and a detection part 1332 that correspond to the detection unit 1330.

A first input terminal 1311a of the comparing part 1311 is electrically connected to an output terminal of the positive-side carrier amplifier, and a second input terminal 1311b of the comparing part 1311 is electrically connected to the reference voltage Vref. An output terminal 1311c of the comparing part 1311 is electrically connected to the DC elimination part 1321.

A first input terminal 1312a of the comparing part 1312 is electrically connected to an output terminal of the negative-side carrier amplifier, and a second input terminal 1312b of the comparing part 1312 is electrically connected to the reference voltage Vref. An output terminal 1312c of the comparing part 1312 is electrically connected to the DC elimination part 1322.

For example, a first terminal of the DC elimination part 1321 is electrically connected to the output terminal 1311c of the comparing part 1311, and a second terminal of the DC elimination part 1321 is electrically connected to the detection part 1331.

For example, a first terminal of the DC elimination part 1322 is electrically connected to the output terminal 1312c of the comparing part 1312, and a second terminal of the DC elimination part 1322 is electrically connected to the detection part 1332.

For example, an input terminal of the detection part 1331 is electrically connected to the second terminal of the DC elimination part 1321, and an output terminal of the detection part 1331 is electrically connected to the detection terminal 1302.

For example, an input terminal of the detection part 1332 is electrically connected to the second terminal of the DC elimination part 1322, and an output terminal of the detection part 1332 is electrically connected to the detection terminal 1302.

Since the detection circuit 1300a includes a differential circuit, leaked odd-order harmonic wave components cancel each other out, and influence of the leakage on the circuit can be suppressed. Accordingly, a filter circuit located subsequent to the detection circuit 1300a to extract a DC component can be omitted. Thus, the delay in the response time can further be reduced in the detection circuit 1300a.

Next, another example of the configuration of the detection circuit 1300a will be described.

As illustrated in FIG. 10, the detection circuit 1300a according to this example includes current sources I2 and I3, in addition to the configuration described above.

The current source I2 is a variable current source in which current is adjustable. For example, the current source I2 is electrically connected to the input terminal of the detection part 1331.

The current source I3 is a variable current source in which current is adjustable. For example, the current source I3 is electrically connected to the input terminal of the detection part 1332.

In the detection circuit 1300a, since the current sources I2 and I3 are provided, currents flowing to resistors R31 and R32 can be finely adjusted without necessarily adjusting the reference voltage V_{ref2}. Therefore, in the detection circuit 1300a, when signals output from the comparing parts 1311 and 1312 are very small, conduction angles of transistors Q31 and Q32 in the detection parts 1331 and 1332 can be adjusted. Furthermore, the detection circuit 1300a can thus appropriately deal with environmental ambient temperature and configuration of a circuit provided downstream thereof.

As described above, the detection circuit 1300a is used for the case where the carrier amplifier 1100 includes a differential circuit. However, the present disclosure is not limited to the configuration described above.

For example, the detection circuit 1300a may include a signal converter (not illustrated in the drawing) that converts the signal RF11 output from the carrier amplifier 1100 into differential signals. Specifically, for example, the signal converter outputs the input signal RF11 as two signal that have substantially opposite phases. The signal converter includes, for example, a balun. “Substantially opposite phases” represents a phase difference of 135 degrees to 225 degrees with respect to a signal.

Accordingly, the detection circuit 1300a that includes a differential circuit can also be used for the carrier amplifier 1100 that is not a differential circuit. Thus, in the detection circuit 1300a, leaked odd-order harmonic wave components cancel each other out, and influence of the leakage on the circuit can be suppressed.

### <<Second Modification>>

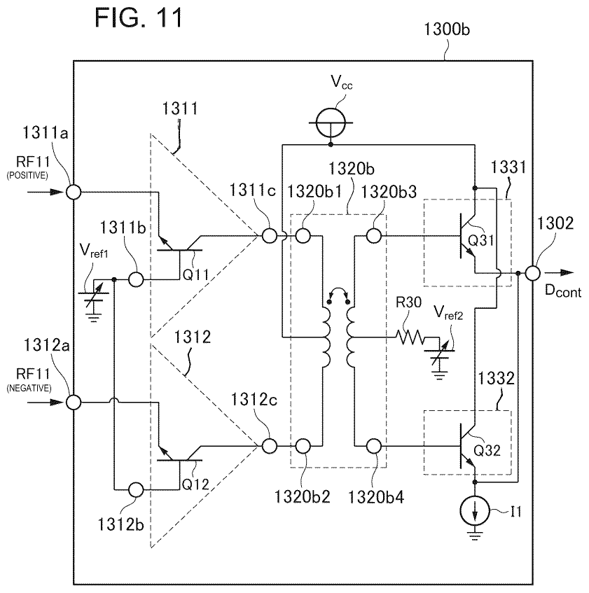

A detection circuit 1300b according to a second modification will be described with reference to FIG. 11. FIG. 11 is a diagram illustrating the configuration of the detection circuit 1300b according to the second modification.

The detection circuit 1300b is obtained by configuring the DC elimination unit 1320 of the detection circuit 1300 as a transformer. In FIG. 11, for example, the DC elimination parts 1321 and 1322 of the detection circuit 1300a illustrated in FIG. 9 are configured as a transformer. Only differences from the detection circuit 1300a illustrated in FIG. 9 will be described below. Unless otherwise stated, the detection circuit 1300b is similar to the detection circuit 1300a.

As illustrated in FIG. 11, the detection circuit 1300b includes a DC elimination unit 1320b that includes a transformer.

The DC elimination unit 1320b includes a pair of input terminals 1320b1 and 1320b2 and a pair of output terminals 1320b3 and 1320b4.

In the DC elimination unit 1320b, the first input terminal 1320b1 is electrically connected to the output terminal 1311c of the comparing part 1311, and the second input terminal 1320b2 is electrically connected to the output terminal 1312c of the comparing part 1312.

In the DC elimination unit 1320b, the first output terminal 1320b3 is electrically connected to the input terminal of the detection part 1331, and the second output terminal 1320b4 is electrically connected to the input terminal of the detection part 1332.

In the detection circuit 1300b, since the DC elimination unit 1320b includes a transformer, a DC component can be eliminated, and the impedance on the load side of the comparing unit 1310 can be increased (hereinafter, referred to as an “increase in impedance”). The detection circuit 1300b achieves the increase in impedance in terms of two points described below.

First, there is a method for achieving an increase in impedance for fundamental waves by impedance conversion of a transformer. Specifically, a higher impedance can be achieved in a transformer by setting the number of turns of a winding on the comparing unit 1310 side to be larger than the number of turns of a winding on the detection unit 1330 side.

Secondly, an increase in impedance can be achieved for even-order harmonic waves. In the detection circuit 1300a, the differential circuit makes odd-order harmonic wave components cancel each other out but does not affect even-order harmonic waves. In contrast, the DC elimination unit 1320b that includes a transformer outputs an in-phase signal for an even-order harmonic wave. That is, when the two input terminals 1320b1 and 1320b2 on the primary side of the transformer are excited in phase, no current flows and an increase in impedance can be achieved.

Thus, in the detection circuit 1300b, the impedance on the load side of the comparing parts 1311 and 1312 can be increased. Therefore, interaction between the inside and the outside thereof can be reduced, and response time can be shortened.

Furthermore, in the detection circuit 1300b, the resistors R11 and R12 connected to the comparing parts 1311 and 1312 can be substituted by a primary winding of a transformer. Thus, whereas a voltage drop due to a DC component occurs in the resistors R11 and R12 in the detection circuit 1300a, a voltage drop due to a DC component can be prevented in the detection circuit 1300b by replacing the resistors R11 and R12 with an inductor of the primary winding of the transformer. That is, variations in a DC component on the load side of the comparing parts 1311 and 1312 caused by the DC component do not occur. Therefore, in the detection circuit 1300b, bias points of the comparing parts 1311 and 1312 (1310) can be fixed, and a quick response time can be achieved.

The current sources I2 and I3 illustrated in FIG. 10 may be provided in the detection circuit 1300b. In this case, the current source I2 is electrically connected to the input terminal of the detection part 1331, and the current source I3 is electrically connected to the input terminal of the detection part 1332.

### <<Third Modification>>

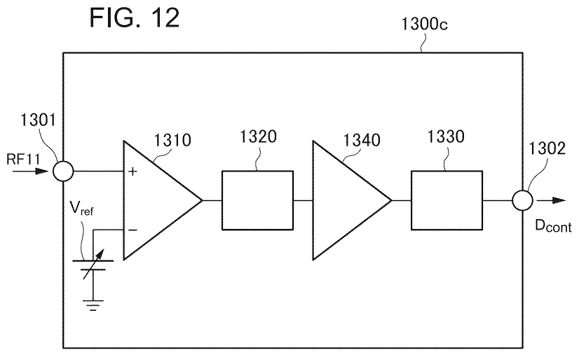

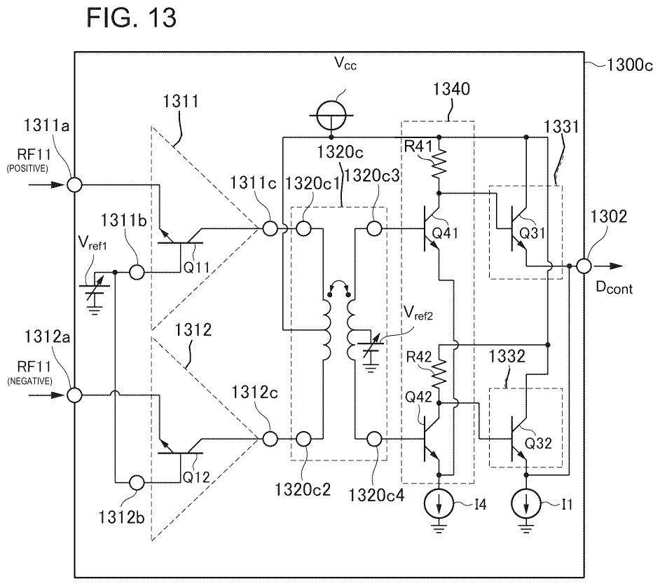

A configuration of a detection circuit 1300c according to a third modification will be described with reference to FIGS. 12 and 13. FIG. 12 is a diagram illustrating a configuration of the detection circuit 1300c according to the third modification. FIG. 13 is a diagram illustrating a specific example of the configuration of the detection circuit 1300c according to the third modification.

Unlike the detection circuit 1300, the detection circuit 1300c is a circuit that includes an amplifier 1340 between the DC elimination unit 1320 and the detection unit 1330.

As illustrated in FIG. 12, in the detection circuit 1300c, the first terminal of the DC elimination unit 1320 is electrically connected to the output terminal of the comparing unit 1310, and the second terminal of the DC elimination unit 1320 is electrically connected to an input terminal of the amplifier 1340. An output terminal of the amplifier 1340 is electrically connected to the input terminal of the detection unit 1330.

In the detection circuit 1300c, since a signal output from the comparing unit 1310 can be large, a signal input to the detection unit 1330 can be large, and the control signal D_{cont} output from the detection terminal 1302 can be large. That is, the detection circuit 1300c can monitor, with an excellent sensitivity, the saturation state of the carrier amplifier 1100.

An example of the specific configuration of the detection circuit 1300c will be described with reference to FIG. 13. In FIG. 13, for example, the configuration in which the amplifier 1340 is added to the detection circuit 1300b illustrated in FIG. 11 is illustrated. That is, for example, the detection circuit 1300c is a circuit in which the amplifier 1340, which is of a differential type, is added to the detection circuit 1300b. Only differences from the detection circuit 1300b illustrated in FIG. 11 will be described below. Unless otherwise stated, the detection circuit 1300c is similar to the detection circuit 1300b.

As illustrated in FIG. 13, the detection circuit 1300c includes the amplifier 1340 that includes transistors. The amplifier 1340 includes a transistor Q41 and a transistor Q42.

For example, the base of the transistor Q41 is electrically connected to the first output terminal 1320c3 of the transformer of the DC elimination unit 1320, the collector of the transistor Q41 is electrically connected to the base of the detection part 1331, and the emitter of the transistor Q41 is electrically connected to a current source I4. Furthermore, the collector of the transistor Q41 is connected to the power source V_{cc} with a resistor R41 interposed therebetween.

For example, the base of the transistor Q42 is electrically connected to the second output terminal 1320c4 of the transformer of the DC elimination unit 1320, the collector of the transistor Q42 is electrically connected to the base of the detection part 1332, and the emitter of the transistor Q42 is electrically connected to the current source I4. Furthermore, the collector of the transistor Q42 is connected to the power source V_{cc} with a resistor R42 interposed therebetween.

Since the detection circuit 1300c includes the differential amplifier 1340, the detection circuit 1300c can eliminate an in-phase signal. Therefore, signals with excellent differential characteristics can be input to the detection unit 1330. This is effective in a situation in which the effect of cancelling out in the differential circuit is small in the case where the gain of the positive-side amplifier is higher than the gain of the negative-side amplifier (for example, design error of a transistor) in the carrier amplifier 1100. That is, the detection circuit 1300c can output a control signal D_{cont} without necessarily the effect of canceling out of differential signals at the output of the detection unit 1330 being degraded.

As described above with reference to FIG. 13, the DC elimination unit 1320 includes a transformer. However, the DC elimination unit 1320 does not necessarily include a transformer. For example, as illustrated in FIG. 10, the DC elimination unit 1320 may include a capacitor.

In this case, the base of the transistor Q41 is electrically connected to a second terminal of a first capacitor (DC elimination unit 1320). Furthermore, the base of the transistor Q42 is electrically connected to a second terminal of a second capacitor (DC elimination unit 1320).

### <<Fourth Modification>>

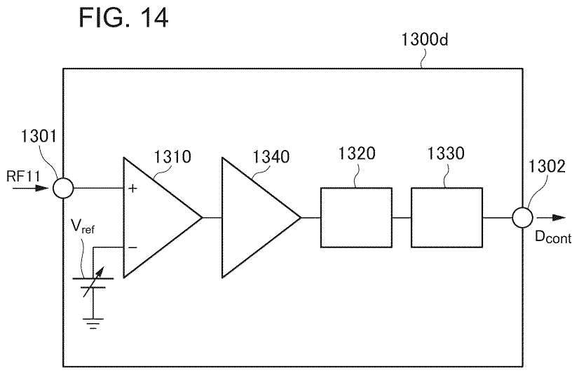

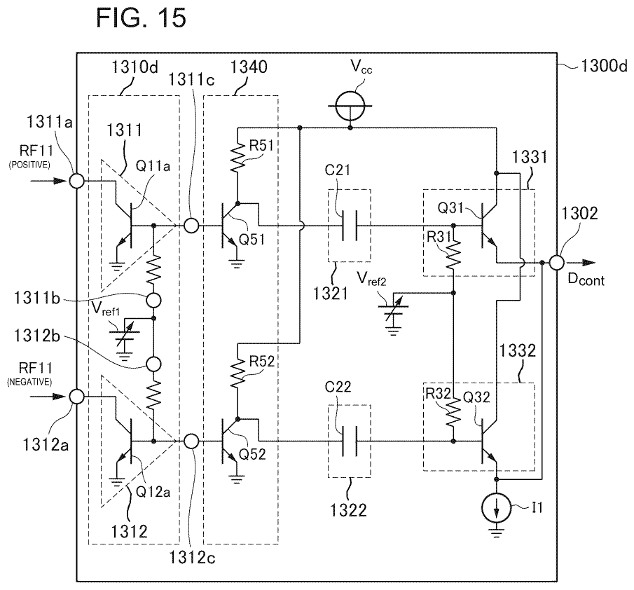

A configuration of a detection circuit 1300d according to a fourth modification will be described with reference to FIGS. 14 and 15. FIG. 14 is a diagram illustrating an example of the configuration of the detection circuit 1300d according to the fourth modification. FIG. 15 is a diagram illustrating another example of the configuration of the detection circuit 1300d according to the fourth modification.

Unlike the detection circuit 1300, the detection circuit 1300d is a circuit that includes the amplifier 1340 between the comparing unit 1310 and the DC elimination unit 1320.

As illustrated in FIG. 14, in the detection circuit 1300d, the output terminal of the comparing unit 1310 is electrically connected to an input terminal of the amplifier 1340, and the output terminal of the amplifier 1340 is electrically connected to the input terminal of the DC elimination unit 1320.

In the detection circuit 1300d, since the output of the comparing unit 1310 and the bias of the amplifier 1340 can be made in common by directly connecting the input terminal of the amplifier 1340 to the output terminal of the comparing unit 1310, the size of the circuit can be reduced. Furthermore, in the detection circuit 1300d, since a signal output from the comparing unit 1310 is amplified by the amplifier 1340 and then input to the DC elimination unit 1320, the capacity of the DC elimination unit 1320 can be reduced.

An example of the specific configuration of the detection circuit 1300d will be described with reference to FIG. 15. In FIG. 15, for example, the configuration in which the emitters of the transistors Q11 and Q12 of the comparing unit 1310 in the detection circuit 1300a illustrated in FIG. 9 are grounded and the amplifier 1340 is added to the detection circuit 1300a is illustrated. Only differences from the detection circuit 1300a illustrated in FIG. 9 will be described below. Unless otherwise stated, the detection circuit 1300d is similar to the detection circuit 1300a.

As illustrated in FIG. 15, the detection circuit 1300d includes a comparing unit 1310d and the amplifier 1340 including transistors.

The comparing unit 1310d includes the comparing part 1311 to which a signal from the positive-side carrier amplifier is input and the comparing part 1312 to which a signal from the negative-side carrier amplifier is input. The comparing part 1311 includes, for example, a transistor Q11a, and the comparing part 1312 includes, for example, a transistor Q12a.

The collector (in this example, a first input terminal) of the transistor Q11a is electrically connected to an output terminal of the positive-side carrier amplifier, the emitter of the transistor Q11a is electrically connected to the ground, and the base (in this example, a second input terminal) of the transistor Q11a is electrically connected to the reference voltage V_{ref1}. Furthermore, the base (in this example, an output terminal) of the transistor Q11a is electrically connected to the base of the transistor Q51 of the amplifier 1340.

The collector (in this example, a first input terminal) of the transistor Q12a is electrically connected to an output terminal of the negative-side carrier amplifier, the emitter of the transistor Q12a is electrically connected to the ground, and the base (in this example, a second input terminal) of the transistor Q12a is electrically connected to the reference voltage V_{ref1}. Furthermore, the base (in this example, an output terminal) of the transistor Q12a is electrically connected to the base of the transistor Q52 of the amplifier 1340.

The amplifier 1340 includes a transistor Q51 and a transistor Q52.

For example, the base of the transistor Q51 is electrically connected to the base of the transistor Q11a of the comparing unit 1310d, the collector of the transistor Q51 is electrically connected to the first terminal of the DC elimination part 1321, and the emitter of the transistor Q51 is electrically connected to the ground. Furthermore, the collector of the transistor Q51 is connected to the power source V_{cc} with a resistor R51 interposed therebetween.

For example, the base of the transistor Q52 is electrically connected to the base of the transistor Q12a of the comparing unit 1310d, the collector of the transistor Q52 is electrically connected to the first terminal of the DC elimination part 1322, and the emitter of the transistor Q52 is electrically connected to the ground. Furthermore, the collector of the transistor Q52 is connected to the power source V_{cc} with a resistor R52 interposed therebetween.

In the case where the comparing unit 1310 is emitter-grounded, while an effect such as a reduction of breakdown of a transistor can be achieved, the amount of increase in the base current of the comparing unit 1310 is small and a signal level that is sufficient to cause the signal to pass through the DC elimination unit 1320 and drive the detection unit 1330 might not be able to be obtained.

Thus, in the detection circuit 1300d, by providing the amplifier 1340 in the stage subsequent to the comparing unit 1310d, a signal output from the comparing unit 1310d can be increased so that the detection unit 1330 can be driven. That is, in the detection circuit 1300d, the detection unit 1330 can be driven reliably, and at the same time, a breakdown of a transistor can be reduced.

As described above, for example, the amplifier 1340 is added to the detection circuit 1300a. However, the amplifier 1340 is not necessarily added to the detection circuit 1300a. For example, the amplifier 1340 may be added to the detection circuit 1300b illustrated in FIG. 11 in which the DC elimination unit 1320 includes a transformer.

In this case, for example, the base of the transistor Q51 is electrically connected to the base of the transistor Q11a of the comparing unit 1310d, the collector of the transistor Q51 is electrically connected to the first input terminal (for example, the input terminal 1320b1 illustrated in FIG. 11) of the DC elimination part 1321 (transformer), and the emitter of the transistor Q51 is electrically connected to the ground.

Furthermore, for example, the base of the transistor Q52 is electrically connected to the base of the transistor Q12a of the comparing unit 1310d, the collector of the transistor Q52 is electrically connected to the second input terminal (for example, the input terminal 1320b2 illustrated in FIG. 11) of the DC elimination part 1322 (transformer), and the emitter of the transistor Q52 is electrically connected to the ground.

### <<Fifth Modification>>

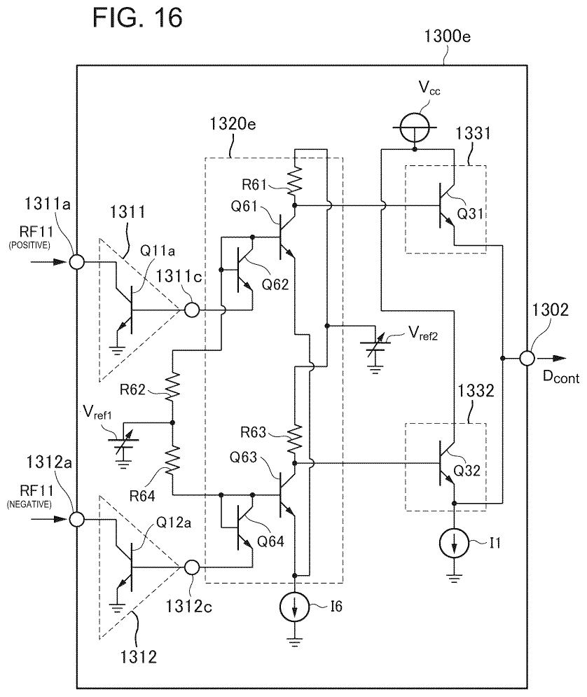

A configuration of a detection circuit 1300e according to a fifth modification will be described with reference to FIG. 16. FIG. 16 is a diagram illustrating a configuration of the detection circuit 1300e according to the fifth modification.

The detection circuit 1300e is configured to, in the case where the carrier amplifier 1100 serves as a differential output, eliminate a DC component by connecting a differential amplifier circuit to output terminals of the pair of comparing parts 1311 and 1312.

Specifically, the detection circuit 1300e includes a differential amplifier circuit 1320e as a DC elimination unit that eliminates a DC component.

The differential amplifier circuit 1320e includes transistors Q61 to Q64 and resistors R61 to R64.

The base of the transistor Q61 is electrically connected to the reference voltage V_{ref1} with the resistor R62 interposed therebetween, the emitter of the transistor Q61 is electrically connected to a current source I6, and the collector of the transistor Q61 is electrically connected to the input terminal (base of the transistor Q31) of the detection part 1331.

The transistor Q62 is a transistor whose base and collector are diode-connected. The base and the collector of the transistor Q62 are electrically connected to the base of the transistor Q61, and the emitter of the transistor Q62 is electrically connected to the base of the comparing part 1311.

The base of the transistor Q63 is electrically connected to the reference voltage V_{ref1} with the resistor R64 interposed therebetween, the emitter of the transistor Q63 is electrically connected to the current source I6, and the collector of the transistor Q63 is electrically connected to the input terminal (base of the transistor Q32) of the detection part 1332.

The transistor Q64 is a transistor whose base and collector are diode-connected. The base and the collector of the transistor Q64 are electrically connected to the base of the transistor Q63, and the emitter of the transistor Q64 is electrically connected to the base of the comparing part 1312.

The collector of the transistor Q61 is electrically connected to the reference voltage V_{ref2} with the resistor R61 interposed therebetween, and the collector of the transistor Q63 is electrically connected to the reference voltage V_{ref2} with the resistor R63 interposed therebetween.

For example, the transistor Q62 and the transistor Q64 are transistor for raising the voltages of the transistor Q61 and the transistor Q63, respectively, by a voltage indicated by the current source I6.

Although the bias of the comparing part 1311 and the transistor Q61 and the bias of the comparing part 1312 and the transistor Q63 are implemented by the reference voltage V_{ref1}, the present disclosure is not limited to this configuration. The bias of each of the comparing part 1311 and the transistor Q61 and the bias of each of the comparing part 1312 and the transistor Q63 may be provided individually. That is, a bias circuit may be provided for each of the transistors. In this case, each of the transistor Q62 and the transistor Q64 that raises a voltage indicated by the current source I6 may be replaced by a capacitor through which a high frequency signal passes.

By using a differential amplifier circuit with a high elimination ratio of in-phase components in order to eliminate a DC component, the detection circuit 1300e can output an appropriate signal for detecting saturation of the carrier amplifier 1100 to the detection unit 1330.

### <<Sixth Modification>>

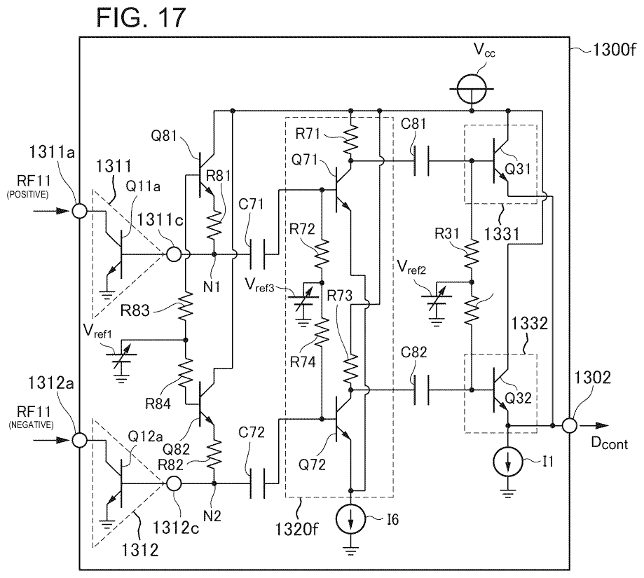

A configuration of a detection circuit 1300f according to a sixth modification will be described with reference to FIG. 17. FIG. 17 is a diagram illustrating the configuration of the detection circuit 1300f according to the sixth modification.

Unlike the detection circuit 1300e, the detection circuit 1300f is a circuit in which a capacitor for eliminating a DC component is provided between a differential amplifier circuit 1320f and the comparing unit 1310 and the differential amplifier circuit 1320f and the comparing unit 1310 are biased by different bias circuits.

The base of the transistor Q11a of the comparing part 1311 is electrically connected to the base of a transistor Q71 of the differential amplifier circuit 1320f with a capacitor C71 interposed therebetween.

Furthermore, the base of the transistor Q11a is electrically connected to the emitter of a transistor Q81 with a resistor R81 interposed therebetween. The base of the transistor Q81 is electrically connected to the reference voltage V_{ref1} with a resistor R83 interposed therebetween, and the collector of the transistor Q81 is electrically connected to the power source V_{cc}.

The base of the transistor Q71 of the differential amplifier circuit 1320f is electrically connected to a reference voltage V_{ref3} with a resistor R72 interposed therebetween, the emitter of the transistor Q71 is electrically connected to a current source I6, and the collector of the transistor Q71 is electrically connected to the power source V_{cc}.

The base of the transistor Q12a of the comparing part 1312 is electrically connected to the base of a transistor Q72 of the differential amplifier circuit 1320f with a capacitor C72 interposed therebetween.

Furthermore, the base of the transistor Q12a is electrically connected to the emitter of a transistor Q82 with the resistor R82 interposed therebetween. The base of the transistor Q82 is electrically connected to the reference voltage V_{ref1} with a resistor R84 interposed therebetween, and the collector of the transistor Q82 is electrically connected to the power source V_{cc}.

The base of the transistor Q72 of the differential amplifier circuit 1320f is electrically connected to the reference voltage V_{ref3} with a resistor R74 interposed therebetween, the emitter of the transistor Q72 is electrically connected to the current source I6, and the collector of the transistor Q72 is electrically connected to the power source V_{cc}.

That is, the reference voltage V_{ref1} supplies, through the transistor Q81, a bias to a node N1 between the output terminal (base) of the comparing part 1311 and the capacitor C71, and supplies, through the transistor Q82, a bias to a node N2 between the output terminal (base) of the comparing part 1312 and the capacitor C72.

In the detection circuit 1300f, a capacitor is provided between the differential amplifier circuit 1320f and the comparing unit 1310 to eliminate a DC component and biases the differential amplifier circuit 1320f and the comparing unit 1310 using different bias circuits.

Thus, by providing the capacitors C71 and C72 in the detection circuit 1300f, a situation in which an output from the comparing unit 1310 flows into a bias circuit for the differential amplifier circuit 1320f and a bias point of the differential amplifier circuit 1320f is thus changed can be prevented. Furthermore, in the detection circuit 1300f, emitter currents of the transistors Q81 and Q82, which are emitter followers, are supplied as bias currents to the node N1 and the node N2, respectively. Thus, for example, also in the case where the comparing parts 1311 and 1312 and the detection parts 1331 and 1332 share part of a bias circuit, an erroneous operation through the bias circuit can be prevented. Since the base currents of the transistors Q81 and Q82, which are emitter followers, are significantly smaller than the emitter currents of the transistors Q81 and Q82, influence on the bias circuit can be reduced in the detection circuit 1300f, and an erroneous operation through the bias circuit can thus be reduced.

The capacitors C81 and C82 illustrated in FIG. 17 are coupling capacitors. The detection circuit 1300f may include such coupling capacitors but does not necessarily include such coupling capacitors.

### <<Seventh Modification>>

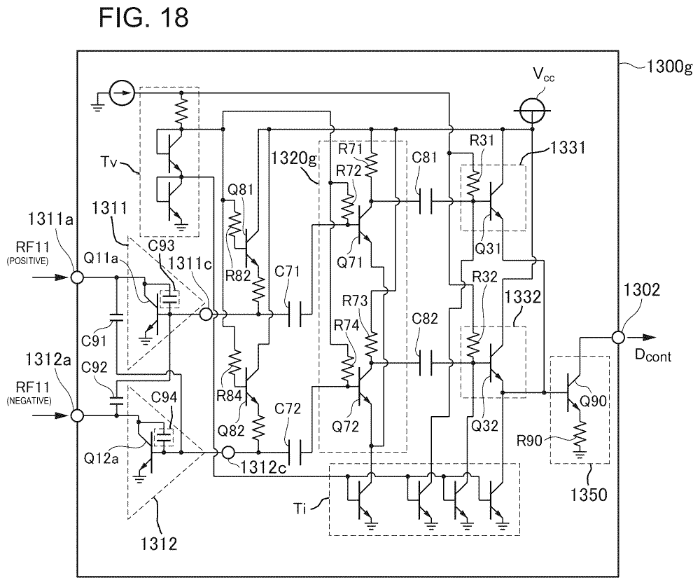

A configuration of a detection circuit 1300g according to a seventh modification will be described with reference to FIG. 18. FIG. 18 is a diagram illustrating the configuration of the detection circuit 1300g according to the seventh modification.

FIG. 18 is a diagram, for example, specifically illustrating, using transistors, a configuration for generating the current sources I1 and I6 and the reference voltages V_{ref1}, V_{ref2}, and V_{ref3} in the detection circuit 1300f illustrated in FIG. 17.

Unlike the detection circuit 1300f, the detection circuit 1300g further includes an amplifier circuit 1350 and capacitors C91 and C92.

For example, the amplifier circuit 1350 amplifies a signal output from the detection unit 1330 and outputs a control signal D_{cont}. For example, the amplifier circuit 1350 includes a transistor Q90 and a resistor R90.

The base of the transistor Q90 is electrically connected to the output terminal (collectors of the transistors Q31 and Q32) of the detection unit 1330, the emitter of the transistor Q90 is connected to the ground with the resistor R90 interposed therebetween, and the collector of the transistor Q90 is electrically connected to the detection terminal 1302.

The resistor R90 is a resistor element that is provided to prevent the voltage between the base and the emitter of the transistor Q90 from becoming too high. By providing the resistor R90 in the amplifier circuit 1350, a breakdown of the transistor Q90 can be prevented.

By providing the amplifier circuit 1350 in the detection circuit 1300g, the control signal D_{cont} at an appropriate signal level can be achieved. Therefore, the detection circuit 1300g can properly detect saturation of the carrier amplifier 1100 (the amplifier in the final stage). Furthermore, the detection circuit 1300g adopts a configuration that uses a threshold voltage between the base and the emitter of a diode-connected transistor as a configuration for generating the reference voltages V_{ref1}, V_{ref2}, and V_{ref3} (“reference voltage transistor Tv” described later). The threshold voltage between the base and the emitter of the transistor Q90 varies in a manner similar to variations in the threshold voltage between the base and the emitter of the reference voltage transistor Tv. Thus, even when there is a change in temperature, a substantially constant collector current can be caused to flow from the transistor Q90 in the detection circuit 1300g.

As described above, the amplifier circuit 1350 is included in the detection circuit 1300g. However, the amplifier circuit 1350 is not necessarily included in the detection circuit 1300g. For example, the amplifier circuit 1350 may be provided as a receiver for the control signal D_{cont} in a bias circuit (for example, a bias circuit for a peak amplifier) that receives the control signal D_{cont} and operates. Furthermore, for example, the amplifier circuit 1350 may be provided as a receiver for the control signal D_{cont} in a variable gain amplifier (for example, a peak amplifier).

The capacitors C91 and C92 are capacitors for canceling parasitic capacitances of the transistors Q11 and Q12. In FIG. 18, the parasitic capacitances are virtually represented by C93 and C94.

A first end of the capacitor C91 is electrically connected to the collector (in this example, the first input terminal) of the transistor Q11a in the comparing part 1311, and a second end of the capacitor C91 is electrically connected to the base (in this example, the output terminal) of the transistor Q12a in the comparing part 1312.

A first end of the capacitor C92 is electrically connected to the collector (in this example, the first input terminal) of the transistor Q12a in the comparing part 1312, and a second end of the capacitor C92 is electrically connected to the base (in this example, the output terminal) of the transistor Q11a in the comparing part 1311.

Due to parasitic capacitance, the transistors Q11 and Q12 may output an excessive output signal even if the signal level of the carrier amplifier 1100 is low. This phenomenon occurs by leakage of a signal input to the comparing parts 1311 and 1312 through parasitic capacitance, as an output signal.

By providing the capacitors C91 and C92 in the detection circuit 1300g, a signal that leaks through a parasitic capacitance to an output can be canceled. Thus, an erroneous operation caused by leakage can be suppressed.

As described above, providing the capacitors C91 and C92 that cancel leakage caused by an input from a differential amplifier (for example, a differential carrier amplifier) in a circuit that detects saturation can be evaluated as achieving remarkable effects compared to related art.

### <<Arrangement of Component Elements>>

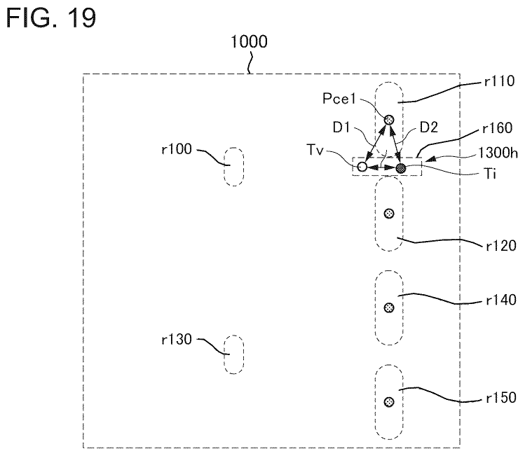

The arrangement of elements of the power amplifier module 1000 will be described with reference to FIG. 19. FIG. 19 is a plan view illustrating the arrangement of component elements of the power amplifier module 1000.

For example, the detection circuit is described as a circuit that has the configuration of the detection circuit 1300g illustrated in FIG. 18. Furthermore, for the sake of convenience, in FIG. 18, a plurality of transistors configuring current sources are collectively referred to as a “current source transistor Ti”, and a plurality of transistors that generate reference voltages are collectively referred to as a “reference voltage transistor Tv”.

In FIG. 19, for example, main heat generation regions on a semiconductor substrate are indicated by broken lines. Specifically, in FIG. 19, a region r100 of a driver-stage amplifier of a carrier amplifier, a region r110 of one of a differential pair of carrier amplifiers, a region r120 of the other one of the differential pair of carrier amplifiers, a region r130 of a driver-stage amplifier of a peak amplifier, a region r140 of one of a differential pair of peak amplifiers, a region r150 of the other one of the differential pair of peak amplifiers, and a region r160 of the detection circuit 1300g are illustrated.

In the power amplifier module 1000, the detection circuit 1300g may be arranged near the final-stage carrier amplifier 1100. Meanwhile, since the final-stage carrier amplifier 1100 consumes high power, the temperature in the vicinity of the final-stage carrier amplifier 1100 is high.

Currents and voltages of the current source transistor Ti and the reference voltage transistor Tv in the detection circuit 1300g vary according to changes in temperature. This is because the voltage between the base and the emitter of the current source transistor Ti and the reference voltage transistor Tv depends on temperature.

That is, in the case where the temperature of the current source transistor Ti and the temperature of the reference voltage transistor Tv change in different manners, the control signal D_{cont} output from the detection terminal 1302 is unstable.

Thus, in the detection circuit 1300g, in order that the temperature of the current source transistor Ti and the temperature of the reference voltage transistor Tv change in a similar manner, the current source transistor Ti and the reference voltage transistor Tv are arranged on the semiconductor substrate. The arrangement relationship between the current source transistor Ti and the reference voltage transistor Tv will be specifically described below.

In the case where the detection circuit 1300g detects saturation of one of the differential pair of carrier amplifiers in the output stage, a distance between a center part Pce1 of the plurality of transistors forming the carrier amplifier and the reference voltage transistor Tv is represented by D1. Furthermore, the distance between the center part Pce1 and the current source transistor Ti is represented by D2. In the detection circuit 1300g, the current source transistor Ti and the reference voltage transistor Tv are arranged in such a manner that the condition represented by Expression (1) is met. That is, the current source transistor Ti and the reference voltage transistor Tv are arranged in such a manner that the condition that the value obtained by dividing the absolute value of the difference between the distance D1 and the distance D2 by the value obtained by adding up the distance D1 and the distance D2 is smaller than “1”.

$$( Math . 1 )$$

$$\vert D 1 - D 2 \vert / ( D 1 + D 2 ) < 1 \qquad ( 1 )$$

The center part Pce1 is, for example, a center point of a region including the plurality of transistors. The center part Pce1 may be, for example, a region including the center point. That is, the center part Pce1 is the highest heat generation point by a heat generation source.

For example, D1 represents the distance between the center part Pce1 and one of the transistors forming the reference voltage transistor Tv that is closest to the center part Pce1. D1 may be, for example, the distance between the center part Pce1 and the center point of the region of the reference voltage transistor Tv.

For example, D2 represents the distance between the center part Pce1 and one of the transistors forming the current source transistor Ti that is closest to the center part Pce1. D2 may be, for example, the distance between the center part Pce1 and the center point of the region of the current source transistor Ti.

As described above, in the detection circuit 1300g, the current source transistor Ti and the reference voltage transistor Tv are arranged in such a manner that a difference between the distance from the current source transistor Ti to one of the differential pair of carrier amplifiers in the output stage and the distance from the reference voltage transistor Tv to the one of the differential pair of carrier amplifiers is small.

In the case where the detection circuit 1300g satisfies the condition represented by Expression (1), the arrangement relationship between the current source transistor Ti and the reference voltage transistor Tv, and amplifiers (for example, the other one of the differential pair of carrier amplifiers in the output stage, a differential pair of peak amplifiers in the output stage, etc.) other than the one of the differential pair of carrier amplifiers in the output stage also satisfies the condition represented by Expression (1).

That is, in the detection circuit 1300g, in the case where the current source transistor Ti, the reference voltage transistor Tv, and at least one heat generation source are arranged in such a manner that Expression (1) is met, the influence of the heat generation source on the current source transistor Ti and the influence of the heat generation source on the reference voltage transistor Tv can be set to similar degrees.

### <<Eighth Modification>>

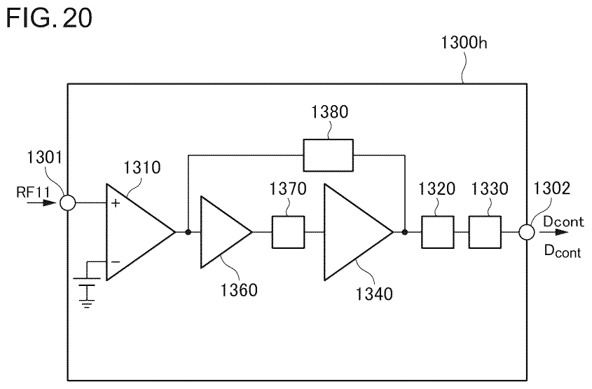

A configuration of a detection circuit 1300h according to an eighth modification will be described with reference to FIG. 20. FIG. 20 is a diagram illustrating a configuration of the detection circuit 1300h according to the eighth modification.

For example, unlike the detection circuit 1300d illustrated in FIG. 14, the detection circuit 1300h is a circuit in which an amplifier 1360 and a DC elimination unit 1370 (intermediate-stage DC elimination unit) are added to the stage upstream the amplifier 1340. Furthermore, for example, the detection circuit 1300h includes a feedback circuit 1380 that feeds a signal output from the amplifier 1340 back to the input of the amplifier 1360. Furthermore, as illustrated in FIG. 15, the detection circuit 1300h is a circuit in which the detection circuit 1300d illustrated in FIG. 15 that includes the transistor Q31 and the transistor Q32 as emitter followers is changed in such a manner that the control signal D_{cont} is output from the collectors of the transistor Q31 and the transistor Q32.

As illustrated in FIG. 20, in the detection circuit 1300h, the output terminal of the comparing unit 1310 is electrically connected to an input terminal of the amplifier 1360, an output terminal of the amplifier 1360 is electrically connected to a first terminal of the DC elimination unit 1370, and a second terminal of the DC elimination unit 1370 is electrically connected to the input terminal of the amplifier 1340. The output terminal of the amplifier 1340 is electrically connected to a first terminal of the feedback circuit 1380, and a second terminal of the feedback circuit 1380 is electrically connected to the input terminal of the amplifier 1360.

Since the detection circuit 1300h includes amplifiers in two stages, detection sensitivity is improved. Furthermore, since the detection circuit 1300h includes the feedback circuit 1380, temperature dependency of the current amplification factor of the amplifiers 1340 and 1360 is suppressed. This is because the current amplification factor of an amplifier circuit that receives an output signal fed back to the input thereof does not depend on changes in temperature but is determined based on the strength of the signal fed back.

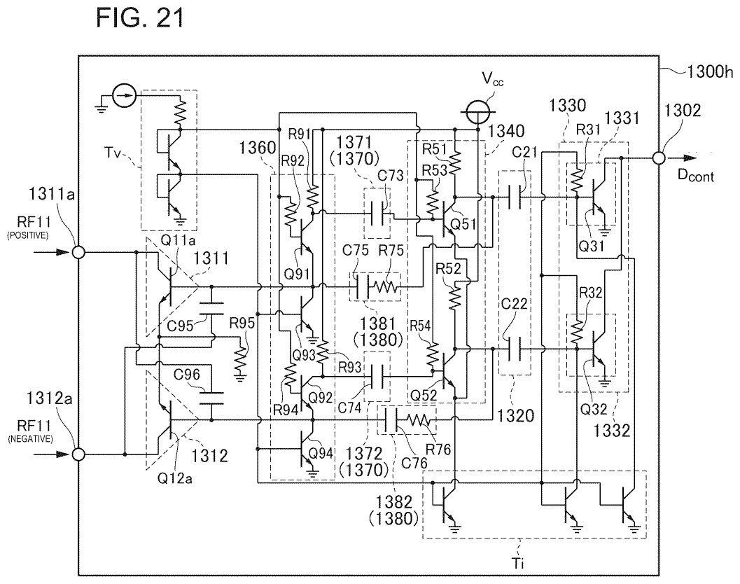

An example of a specific configuration of the detection circuit 1300h will be described with reference to FIG. 21. FIG. 21 is a diagram illustrating a specific example of the configuration of the detection circuit 1300h according to the eighth modification. Only differences from the detection circuit 1300d illustrated in FIG. 15 will be described below. Unless otherwise stated, the detection circuit 1300h is similar to the detection circuit 1300d. In FIG. 21, for example, a configuration for generating the current sources I1 and I6 and the reference voltages V_{ref1} and V_{ref2} (hereinafter, collectively referred to as a “reference voltage”) in the detection circuit 1300d illustrated in FIG. 15 is specifically illustrated using transistors.

As illustrated in FIG. 21, the detection circuit 1300h includes the amplifier 1360, the DC elimination unit 1370, and the feedback circuit 1380.

The amplifier 1360 includes transistors Q91 to Q94 and resistors R91 to R94.

The reference voltage is supplied to the base of the transistor Q91. The emitter of the transistor Q91 is electrically connected to the base of the transistor Q11a of the comparing part 1311, and the collector of the transistor Q91 is connected to the power source V_{cc} with the resistor R91 interposed therebetween. Furthermore, the emitter of the transistor Q91 is electrically connected to the ground with the transistor Q93 interposed therebetween.

The reference voltage is supplied to the base of the transistor Q92. The emitter of the transistor Q92 is electrically connected to the base of the transistor Q12a of the comparing part 1312, and the collector of the transistor Q92 is connected to the power source V_{cc} with the resistor R93 interposed therebetween. Furthermore, the emitter of the transistor Q92 is electrically connected to the ground with the transistor Q94 interposed therebetween.

The DC elimination unit 1370 includes a DC elimination part 1371 including a capacitor C73 and a DC elimination part 1372 including a capacitor C74. A first terminal of the capacitor C73 is electrically connected to the collector of the transistor Q91, and a second terminal of the capacitor C73 is electrically connected to the base of the transistor Q51 of the amplifier 1340. A first terminal of the capacitor C74 is electrically connected to the collector of the transistor Q92, and a second terminal of the capacitor C74 is electrically connected to the base of the transistor Q52 of the amplifier 1340.

The feedback circuit 1380 includes a feedback circuit 1381 and a feedback circuit 1382. The feedback circuit 1381 includes, for example, a capacitor C75 and a resistor R75 that are connected in series. A first end of the feedback circuit 1381 is electrically connected to the collector of the transistor Q51, and a second end of the feedback circuit 1381 is electrically connected to the emitter of the transistor Q91. A first end of the feedback circuit 1382 is electrically connected to the collector of the transistor Q52, and a second end of the feedback circuit 1382 is electrically connected to the emitter of the transistor Q92.

As described above, in the detection circuit 1300h, a bias is supplied through the transistor Q91 to the base of the transistor Q11a of the comparing part 1311, and a bias is supplied through the transistor Q92 to the base of the transistor Q12a of the comparing part 1311. That is, the transistors Q91 and Q92 supply biases to the comparing parts 1311 and 1312, respectively, amplify signals output from the comparing parts 1311 and 1312, respectively, and transmit signals to the detection parts 1331 and 1332, respectively, in the downstream. Thus, in the detection circuit 1300h, with the use of a single transistor (in this example, each of the transistors Q91 and Q92) for bias supply and signal amplification, the size of the circuit can be reduced.

Furthermore, in the detection circuit 1300h, the transistors Q91 and Q92 are electrically connected to the ground with the transistors Q93 and Q94, respectively, interposed therebetween. With the provision of the transistors Q93 and Q94, current can be drawn from the emitter of the transistor Q91 and the emitter of the transistor Q92 using the collector currents of the transistor Q93 and the transistor Q94, respectively. That is, appropriate bias currents can be caused to flow to the transistor Q91 and the transistor Q92. Thus, the current amplification factor of each of the transistor Q91 and the transistor Q92 can be maintained relatively high, and excellent signal amplification characteristics by the transistors Q91 and Q92 described above can be achieved.

The base of the transistor Q31 in the detection unit 1330 is connected in series to the capacitor C21 of the DC elimination unit 1320, the emitter of the transistor Q31 is electrically connected to the ground, and the collector of the transistor Q31 is electrically connected to the detection terminal 1302. Furthermore, the base of the transistor Q32 in the detection unit 1330 is connected in series to the capacitor C22 of the DC elimination unit 1320, the emitter of the transistor Q32 is electrically connected to the ground, and the collector of the transistor Q32 is electrically connected to the detection terminal 1302. That is, in the detection unit 1330, the control signal D_{cont} obtained by combining a signal (first control signal) output from the collector of the transistor Q31 and a signal (second control signal) output from the collector of the transistor Q32 is output from the detection terminal 1302. For example, the transistors Q31 and Q32 smooth high frequency components into DC by using capacitors (not illustrated in the drawing) for smoothing high frequency signals and output the smoothed high frequency components. By connecting the collectors of the transistors Q31 and Q32 to the detection terminal 1302, the size of a filter circuit (not illustrated in the drawing) connected to the detection terminal 1302 can be reduced.

Furthermore, the capacitors C95 and C96 provided in the comparing parts 1311 and 1312, respectively, are capacitors for canceling parasitic capacitances of the transistor Q11a and the transistor Q12a, respectively.

### <<Arrangement on Substrate>

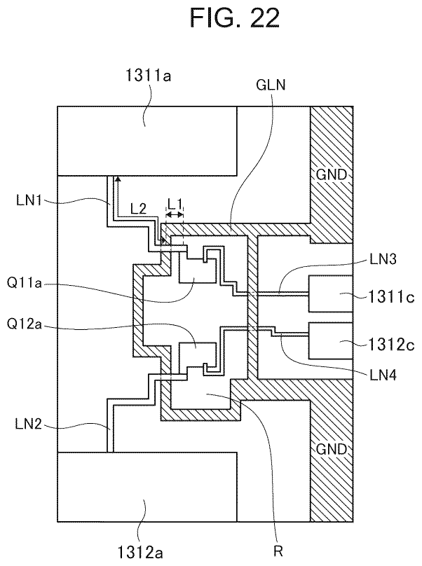

The arrangement of the detection circuit 1300h according to the eighth modification on the substrate will be described with reference to FIG. 22. FIG. 22 is a diagram illustrating an example of the arrangement of the detection circuit 1300h according to the eighth modification on the substrate. FIG. 22 is a diagram when the detection circuit 1300h arranged on the substrate is seen in plan view from a direction perpendicular to a substrate surface. For example, the arrangement of the detection circuit 1300h according to the eighth modification on the substrate will be described below. However, this arrangement is also applicable to, for example, the detection circuits 1300d, 1300e, 1300f, and 1300g in a similar manner.

In the detection circuit 1300h, a wire LN1 between the transistor Q11a (third transistor) and an input terminal 1311a and a wire LN2 between the transistor Q12a (fourth transistor) and an input terminal 1312a are arranged in such a manner that the wire LN1 and the wire LN2 can avoid magnetic field coupling to a wire LN3 between the transistor Q11a and an output terminal 1311c and a wire LN4 between the transistor Q12a and an output terminal 1312c, respectively.

In the detection circuit 1300h, signals flowing through the wire LN3 and the wire LN4 connected to the bases of the transistors are used as signals for outputting a control signal D_{cont}. A current flowing to the base of a transistor is weak. In contrast, a current flowing to the collector of the transistor is significantly large compared to the current flowing to the base of the transistor. A problem occurs in which large currents flowing through the wire LN1 and the wire LN2 flow to the wire LN3 and the wire LN4, respectively, due to magnetic field coupling. In this case, in the state in which the carrier amplifier 1100 is not saturated, the detection unit 1330 outputs a control signal D_{cont}. Thus, the detection circuit 1300h is arranged on the substrate in order that the erroneous operation mentioned above does not occur.

The collector of the transistor Q11a is electrically connected to the input terminal 1311a to which a signal RF11 output from a first carrier amplifier 1100 is input, the emitter of the transistor Q11a is electrically connected to the ground, and the base of the transistor Q11a is electrically connected to the output terminal 1311c of the comparing part 1311 (a terminal connected to the bases of the transistor Q31 and the transistor Q51 in FIG. 21).

Furthermore, the collector of the transistor Q12a is electrically connected to the input terminal 1312a to which a signal RF12 output from a second carrier amplifier 1100 is input, the emitter of the transistor Q12a is electrically connected to the ground, and the base of the transistor Q12a is electrically connected to the output terminal 1312c of the comparing part 1312 (a terminal connected to the bases of the transistor Q32 and the transistor Q52 in FIG. 21).

As illustrated in FIG. 22, in a plan view, the transistor Q11a is provided inside a region R surrounded by a ground wire GLN that is electrically connected to a ground layer GND. The transistor Q12a is, in a plan view, provided inside the region R surrounded by the ground wire GLN that is electrically connected to the ground layer GND.

In contrast, the input terminal 1311a is provided outside the region R surrounded by the ground wire GLN. Furthermore, the input terminal 1312a is provided outside the region R surrounded by the ground wire GLN.

In other words, for example, the ground wire GLN is provided to electromagnetically isolate the wires LN3 and LN4 connected to the bases of the transistors Q11a and Q12a, respectively, from the wires LN1 and LN2 connected to the collectors of the transistors Q11a and Q12a, respectively.

As described above, the detection circuit 1300h is arranged on the substrate in such a manner that the ground wire GLN electromagnetically isolates the wires LN1 and LN2 connected to the collectors of the transistors Q11a and Q12a, respectively, from the wires LN3 and LN4 connected to the bases of the transistors Q11a and Q12a, respectively. Thus, an erroneous operation of the detection circuit 1300h can be prevented.

As illustrated in FIG. 22, the transistor Q11a and the transistor Q12a are surrounded together by the ground wire GLN. However, the present disclosure is not limited to this arrangement. For example, the transistor Q11a and the transistor Q12a may be individually surrounded by the ground wire GLN. Furthermore, for example, the ground layer GND is provided at a layer that is different from the layer at which the wires LN1 to LN4 are provided.

Furthermore, the transistor Q11a is provided in such a manner that a length L1, in plan view, of a part of the wire LN1 that is inside the region R surrounded by the ground wire GLN is shorter than a length L2, in plan view, of a part of the wire LN1 that is outside the region R. Similarly, the transistor Q12a is provided in such a manner that a length inside the region R in plan view is shorter than a length outside the region R a plan view, as to LN2. Thus, an erroneous operation of the detection circuit 1300h can be prevented more reliably.

### <<Ninth Modification>>

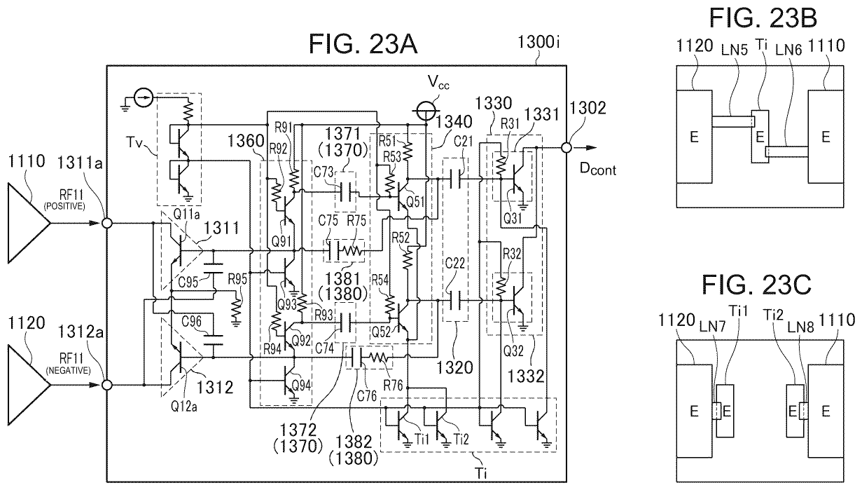

A configuration of a detection circuit 1300i according to a ninth modification will be described below with reference to FIGS. 23A to 23C. FIGS. 23A to 23C include diagrams illustrating the configuration of the detection circuit 1300i according to the ninth modification. FIG. 23B and FIG. 23C are plan views visually recognized from above the detection circuit 1300i and are schematic diagrams for understanding of extension of wires.

As illustrated in FIG. 23A, for example, unlike the detection circuit 1300h illustrated in FIG. 21, in the detection circuit 1300i, the current source transistor Ti connected in series between the emitters of the transistors Q51 and Q52 forming the amplifier 1340 and the ground includes a transistor Ti1 and a transistor Ti2 whose collectors are connected to each other.

In FIGS. 23A to 23C, a collector, which is an output, of the final-stage amplifier 1100 including a differential circuit is connected to the input of the detection circuit 1300i. The emitter of the final-stage amplifier 1100 is electrically connected to a ground wire. Furthermore, in the description provided below, a positive-side amplifier of the final-stage amplifier 1100 will be referred to as an amplifier 1110, and a negative-side amplifier of the final-stage amplifier 1100 will be referred to as an amplifier 1120.

In the case where the current source transistor Ti is a single transistor, the emitters of the amplifiers 1110 and 1120 in the final stage connected to the input of the detection circuit 1300i need to be connected to the emitter of the same current source transistor Ti on the substrate. As illustrated in FIG. 23B, a ground wire LN5 for connecting the emitter of the negative-side amplifier 1120 to the emitter of the current source transistor Ti and a ground wire LN6 for connecting the emitter of the positive-side amplifier 1110 to the emitter of the current source transistor Ti need to be laid around a certain distance. Thus, in the case where the current source transistor Ti is provided in common for the transistors Q51 and Q52, the ground wires LN5 and LN6 for connecting the transistors to the current source transistor Ti may be coupled to other wires included in the detection circuit 13001 and the detection circuit 1300i may operate erroneously.

In contrast, as illustrated in FIG. 23A, in the case where the current source transistor Ti includes the separate transistors Ti1 and Ti2 whose collectors are connected to each other, the transistors Ti1 and Ti2 may be arranged on the substrate in such a manner that the transistors Ti1 and Ti2 are adjacent to amplifiers connected to the input of the detection circuit 1300i. Thus, as illustrated in FIG. 23C, a wire LN7 for connecting the emitter of the transistor Ti1 to the emitter of the negative-side amplifier 1120 and a wire LN8 for connecting the emitter of the transistor Ti2 to the emitter of the positive-side amplifier 1110 can be arranged to be relatively short in length. Therefore, the wires LN7 and LN8 are not easily coupled to other wires included in the detection circuit 1300i, and an erroneous operation of the detection circuit 1300i can be easily suppressed.

Furthermore, as illustrated in FIG. 23A. in the case where the current source transistor Ti includes the separate transistors Ti1 and Ti2 whose collectors are connected to each other, a collector current flowing in the transistor Ti1 and a collector current flowing in the transistor Ti2 are added up at the collectors that are connected to each other. Thus, even if currents flowing in the transistors Ti1 and Ti2 are not in balance, the unbalanced currents are made to be balanced by adding up the currents. Therefore, the amplifiers connected to the input of the detection circuit 1300i operate in a balanced state. Thus, an erroneous operation of the detection circuit 1300i can further be suppressed.

Furthermore, in the case where the current source transistor Ti includes the separate transistors Ti1 and Ti2 whose collectors are connected to each other, both the current transistors Ti1 and Ti2 are connected to each of the transistors Q51 and Q52. Thus, even if amplifiers connected to the input of the detection circuit 1300i operate in an unbalanced manner due to some reason, because the influence of the unbalanced operation is distributed to the transistors Ti1 and Ti2, variations in the characteristics of the amplifier 1340 can be suppressed eventually.

### <<Other Modifications of Power Amplifier Module>>

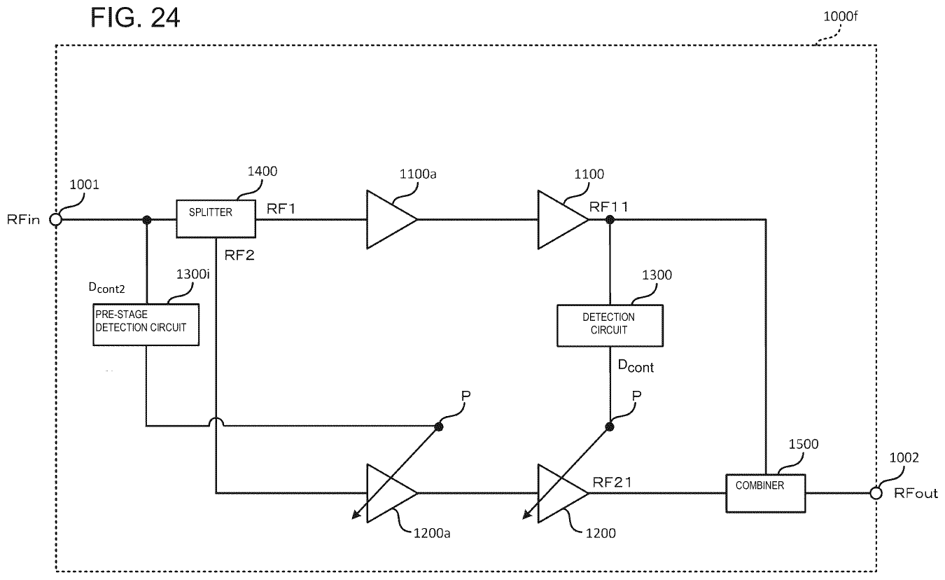

Other modifications of the configuration of the power amplifier module 1000 will be described below with reference to FIG. 24. FIG. 24 is a diagram illustrating the configuration of a power amplifier module 1000f according to another modification. Only configuration features different from those of the power amplifier module 1000a according to the first modification will be described below.

In a power amplifier module that includes a Doherty amplifier circuit including amplifiers in multiple stages, for example, in the case where the degree of saturation of a final-stage carrier amplifier is not high in spite of the high signal level of an input signal RFin, there is a problem in which while a bias point of a driver-stage peak amplifier approaches class A, a bias point of a final-stage peak amplifier is class C. In this case, since the total gain of the final-stage peak amplifier and the driver-stage peak amplifier is low, the peak amplifiers do not operate. Thus, distortion characteristics of the power amplifier module are not improved. The power amplifier module 1000f has a configuration that can resolve the problem mentioned above.

As illustrated in FIG. 24, in the power amplifier module 1000f, the detection circuit 1300 outputs a control signal D_{cont} to the final-stage peak amplifier 1200. Furthermore, the power amplifier module 1000f further includes a pre-stage detection circuit 1300i. The pre-stage detection circuit 1300i outputs, based on the signal level of the input signal RFin, a control signal D_{cont2} to the driver-stage peak amplifier 1200a. For example, the control signal D_{cont2} is input to the driver-stage peak amplifier 1200a or a bias circuit (not illustrated in the drawing) for the peak amplifier 1200a. Thus, a bias point of the driver-stage peak amplifier 1200a is set.

As described above, in the power amplifier module 1000f, the bias point of the final-stage peak amplifier 1200 is set according to the degree of saturation of the final-stage carrier amplifier 1100, and the bias point of the drive-stage peak amplifier 1200a is set according to the strength of the signal level of the input signal RFin. Thus, the power amplifier module 1000f can cause the drive-stage peak amplifier 1200a and the final-stage peak amplifier 1200 to operate at appropriate timing.

### CONCLUSION

<1> A detection circuit 1300 of an power amplifier module 1000 according to an illustrative embodiment of the present disclosure includes a comparing unit 1310 that receives a signal output from an output terminal of a predetermined amplifier (for example, a carrier amplifier 1100, an amplifier 1100 in a final stage illustrated in FIG. 5) and a reference voltage Vref and outputs, through an output terminal 1310c, a first output signal corresponding to a difference between a signal level (for example, a voltage) of the signal output from the predetermined amplifier and the reference voltage Vref; a DC elimination unit 1320 whose first terminal is electrically connected to the output terminal 1310c of the comparing unit 1310, a signal obtained by eliminating a DC component of the first output signal being output through a second terminal of the DC elimination unit 1320; and a detection unit 1330 whose input terminal is electrically connected to the second terminal of the DC elimination unit 1320, a control signal D_{cont} corresponding to the signal level of the signal output from the predetermined amplifier being output through an output terminal of the detection unit 1330. As described above, the detection circuit 1300 includes the DC elimination unit 1320 that is provided between the comparing unit 1310 and the detection unit 1330 in order that an unstable DC component output from the comparing unit 1310 does not affect the detection unit 1330. Accordingly, the detection circuit 1300 can quickly detect saturation of a carrier amplifier in a Doherty amplifier circuit. Thus, a peak amplifier in the Doherty amplifier circuit can be caused to operate at an appropriate timing. Furthermore, since saturation of the amplifier in the final stage can be quickly detected, an amplifier in a drive stage can be controlled properly.

<2> The DC elimination unit 1320 of the detection circuit 1300 in the power amplifier module 1000 according to an illustrative embodiment of the present disclosure includes a capacitor whose first terminal is electrically connected to the output terminal 1310c of the comparing unit 1310, the signal obtained by eliminating the DC component of the first output signal being output through a second terminal of the capacitor. Accordingly, a DC component can be eliminated with a compact and simplified configuration.

<3> In the detection circuit according to <1> or <2>, the comparing unit 1310 of the detection circuit 1300 in the power amplifier module 1000 according to an illustrative embodiment of the present disclosure includes a transistor Q10 whose emitter or source is electrically connected to the output terminal of the predetermined amplifier, whose base or gate is electrically connected to the reference voltage Vref, and whose collector or drain is electrically connected to the first terminal of the DC elimination unit 1320. Accordingly, a comparing unit with a rapid response speed can be achieved.

<4> In the detection circuit according to <1> or <2>, the comparing unit 1310 of the detection circuit 1300 in the power amplifier module 1000 according to an illustrative embodiment of the present disclosure includes a transistor Q11a or Q12a whose emitter or source is electrically connected to a ground, whose collector or drain is electrically connected to the output terminal of the predetermined amplifier, and whose base or gate is electrically connected to the reference voltage and electrically connected to the first terminal of the DC elimination unit 1320. Accordingly, compared with a case where a base-grounded transistor is used, a breakdown of the transistor can be reduced.

<5> In the DC current according to any one of <1> to <4>, the detection unit 1330 of the detection circuit 1300 in the power amplifier module 1000 according to an illustrative embodiment of the present disclosure includes a transistor Q30 whose base or gate is electrically connected to the second terminal of the DC elimination unit 1320 and whose collector or drain is electrically connected to a power source, the control signal D_{cont} being output through an emitter or a source of the transistor Q30. Accordingly, an interaction in an AC manner between the comparing unit 1310 and the detection unit 1330 can be suppressed.

<6> In the detection circuit according to <1> or <2>, as a detection circuit 1300a of the power amplifier module 1000 according to an illustrative embodiment of the present disclosure, the predetermined amplifier is a differential amplifier that includes a positive-side carrier amplifier (first amplifier) and a negative-side carrier amplifier (second amplifier). The comparing unit 1310 includes a comparing part 1311 (first comparing part) that receives a signal output from an output terminal of the positive-side carrier amplifier (first amplifier) and a reference voltage V_{ref1} and outputs, through an output terminal 1311c (first output terminal), a second output signal corresponding to a difference between a signal level of the signal output from the positive-side carrier amplifier (first amplifier) and the reference voltage V_{ref1}, and a comparing part 1312 (second comparing part) that receives a signal output from an output terminal of the negative-side carrier amplifier (second amplifier) and the reference voltage V_{ref1} and outputs, through an output terminal 1312c (second output terminal), a third output signal corresponding to a difference between a signal level of the signal output from the negative-side carrier amplifier (second amplifier) and the reference voltage V_{ref1}. The DC elimination unit 1320 includes a DC elimination part 1321 (first DC elimination part) whose first terminal is electrically connected to the output terminal 1311c (first output terminal) of the comparing part 1311 (first comparing part), a signal obtained by eliminating a DC component of the second output signal being output through a second terminal of the DC elimination part 1321, and a DC elimination part 1322 (second DC elimination part) whose first terminal is electrically connected to the output terminal 1312c (second output terminal) of the comparing part 1312 (second comparing part), a signal obtained by eliminating a DC component of the third output signal being output through a second terminal of the DC elimination part 1322. The detection unit 1330 includes a detection part 1331 (first detection part) whose input terminal is electrically connected to the second terminal of the DC elimination part 1321 (first DC elimination part), a first control signal corresponding to the signal level of the signal output from the positive-side carrier amplifier (first amplifier) being output through an output terminal of the detection part 1331, and a detection part 1332 (second detection part) whose input terminal is electrically connected to the second terminal of the DC elimination part 1322 (second DC elimination part), a second control signal corresponding to the signal level of the signal output from the negative-side carrier amplifier (second amplifier) being output through an output terminal of the detection part 1332. Accordingly, leaked odd-order harmonic wave components can cancel each other out, and influence of the leakage on the circuit can be suppressed.

<7> In the detection circuit according to <1> or <2>, as a detection circuit 1300b of the power amplifier module 1000 according to an illustrative embodiment of the present disclosure, the predetermined amplifier is a differential amplifier that includes a positive-side carrier amplifier (first amplifier) and a negative-side carrier amplifier (second amplifier). The comparing unit 1310 includes a comparing part 1311 (first comparing part) that receives a signal output from an output terminal of the positive-side carrier amplifier (first amplifier) and a reference voltage V_{ref1} and outputs, through an output terminal 1311c (first output terminal), a second output signal corresponding to a difference between a signal level of the signal output from the positive-side carrier amplifier (first amplifier) and the reference voltage V_{ref1}, and a comparing part 1312 (second comparing part) that receives a signal output from an output terminal of the negative-side carrier amplifier (second amplifier) and the reference voltage V_{ref1} and outputs, through an output terminal 1312c (an electrically connected second output terminal), a third output signal corresponding to a difference between a signal level of the signal output from the negative-side carrier amplifier (second amplifier) and the reference voltage V_{ref1}. The DC elimination unit 1320 includes a transformer that includes a pair of input terminals 1320b1 and 1320b2 and a pair of output terminals 1320b3 and 1320b4. A first input terminal of the pair of input terminals 1320b1 and 1320b2 is electrically connected to an output terminal of the comparing part 1311 (first comparing part), and a second input terminal of the pair of input terminals 1320b1 and 1320b2 is electrically connected to an output terminal of the comparing part 1312 (second comparing part). The detection unit 1330 includes a detection part 1331 (first detection part) whose input terminal is electrically connected to the output terminal 1320b3 of the DC elimination unit 1320, a first control signal corresponding to the signal level of the signal output from the positive-side carrier amplifier (first amplifier) being output through an output terminal of the detection part 1331, and a detection part 1332 (second detection part) whose input terminal is electrically connected to the output terminal 1320b4 of the DC elimination unit 1320, a second control signal corresponding to the signal level of the signal output from the negative-side carrier amplifier (second amplifier) being output through an output terminal of the detection part 1332. Accordingly, a DC component can be eliminated, and impedance on the load side of the comparing unit 1310 can be increased.

<8> The detection circuit according to <6> or <7>, as the detection circuit 1300a or 1300b of the power amplifier module 1000 according to an illustrative embodiment of the present disclosure, further includes at least one of a current source I2 (first variable current source) that is electrically connected to the input terminal of the detection part 1331 (first detection part) and is capable of adjusting a current, and a current source I3 (second variable current source) that is electrically connected to the input terminal of the detection part 1332 (second detection part) and is capable of adjusting a current. Accordingly, when a signal output from the comparing unit 1310 (1311, 1312) is very small, the signal can be adjusted.

<9> The detection circuit according to <6> or <7>, as the detection circuits 1300a to 1300g of the power amplifier module 1000 according to an illustrative embodiment of the present disclosure further includes a first capacitor whose first end is electrically connected to the input terminal of the comparing part 1311 (first comparing part) and whose second end is electrically connected to the output terminal of the comparing part 1312 (second comparing part), and a second capacitor whose first end is electrically connected to the input terminal of the comparing part 1312 (second comparing part) and whose second end is electrically connected to the output terminal of the comparing part 1311 (first comparing part). Accordingly, since a leaked signal output through a parasitic capacitance can be canceled, an erroneous operation due to leakage can be suppressed.

<10> The detection circuit according to any one of <1> to <5>, as the detection circuit 1300c of the power amplifier module 1000 according to an illustrative embodiment of the present disclosure, further includes an amplifier 1340 whose input terminal is electrically connected to the second terminal of the DC elimination unit 1320 and whose output terminal is electrically connected to the input terminal of the detection unit 1330. Accordingly, the detection circuit 1300c can monitor, with an excellent sensitivity, the saturation state of the carrier amplifier 1100.

<11> The detection circuit according to any one of <6>, <8>, <9>, and <10>, as the detection circuit 1300c of the power amplifier module 1000 according to an illustrative embodiment of the present disclosure, further includes a transistor Q41 (third amplifier) whose input terminal is electrically connected to the second terminal of the DC elimination part 1321 (first DC elimination part) and whose output terminal is electrically connected to the input terminal of the detection part 1331 (first detection part), and a transistor Q42 (fourth amplifier) whose input terminal is electrically connected to the second terminal of the DC elimination part 1322 (second DC elimination part) and whose output terminal is electrically connected to the input terminal of the detection part 1332 (second detection part). Accordingly, the detection circuit 1300c can output a control signal D_{cont} without necessarily the effect of canceling out of differential signals at the output of the detection unit 1330 being degraded.

<12> The detection circuit according to any one of <7> to <10>, as the detection circuit 1300c of the power amplifier module 1000 according to an illustrative embodiment of the present disclosure, further includes a transistor Q41 (third amplifier) whose input terminal is electrically connected to a first output terminal 1320c3 of a DC elimination unit 1320c and whose output terminal is electrically connected to the input terminal of the detection part 1331 (first detection part), and a transistor Q42 (fourth amplifier) whose input terminal is electrically connected to an output terminal 1320c4 of the DC elimination unit 1320c and whose output terminal is electrically connected to the input terminal of the detection part 1332 (second detection part). Accordingly, the detection circuit 1300c can output a control signal D_{cont} without necessarily the effect of canceling out of differential signals at the output of the detection unit 1330 being degraded.

<13> The detection circuit according to any one of <1> to <5>, as a detection circuit 1300d of the power amplifier module 1000 according to an illustrative embodiment of the present disclosure, further includes an amplifier 1340 whose input terminal is electrically connected to the output terminal of the comparing unit 1310 and whose output terminal is electrically connected to the first terminal of the DC elimination unit 1320. Accordingly, the capacity of the DC elimination unit 1320 can be reduced.

<14> The detection circuit according to any one of <6>, <8>, <9>, and <10>, as the detection circuit 1300d of the power amplifier module 1000 according to an illustrative embodiment of the present disclosure, further includes a transistor Q51 (third amplifier) whose input terminal is electrically connected to the output terminal 1311c of the comparing part 1311 (first comparing part) and whose output terminal is electrically connected to the first terminal of the DC elimination part 1321 (first DC elimination part), and a transistor Q52 (fourth amplifier) whose input terminal is electrically connected to the output terminal 1312c of the comparing part 1312 (second comparing part) and whose output terminal is electrically connected to the first terminal of the DC elimination part 1322 (second DC elimination part). Accordingly, in the detection circuit 1300d, the detection unit 1330 can be driven reliably, and at the same time, a breakdown of a transistor can be reduced.

<15> The detection circuit according to any one of <7> to <10>, as the detection circuit 1300d of the power amplifier module 1000 according to an illustrative embodiment of the present disclosure, further includes a transistor Q51 (third amplifier) whose input terminal is electrically connected to the output terminal 1311c of the comparing part 1311 (first comparing part) and whose output terminal is electrically connected to the first input terminal of the DC elimination unit 1320, and a transistor Q52 (fourth amplifier) whose input terminal is electrically connected to the output terminal of the comparing part 1312 (second comparing part) and whose output terminal is electrically connected to the second input terminal of the DC elimination unit 1320. Accordingly, in the detection circuit 1300d, the detection unit 1330 can be driven reliably, and at the same time, a breakdown of a transistor can be reduced.

<16> In the detection circuit according to any one of <1> to <5>, as a detection circuit 1300e of the power amplifier module 1000 according to an illustrative embodiment of the present disclosure, the predetermined amplifier is a differential amplifier that includes a positive-side carrier amplifier (first amplifier) and a negative-side carrier amplifier (second amplifier). The comparing unit 1310 includes a comparing part 1311 (first comparing part) that receives a signal output from an output terminal of the positive-side carrier amplifier (first amplifier) and a reference voltage V_{ref1} and outputs, through an output terminal 1311c, a second output signal corresponding to a difference between a signal level of the signal output from the positive-side carrier amplifier (first amplifier) and the reference voltage, and a comparing part 1312 (second comparing part) that receives a signal output from an output terminal of the negative-side carrier amplifier (second amplifier) and the reference voltage V_{ref1} and outputs, through an output terminal 1312c, a third output signal corresponding to a difference between a signal level of the signal output from the negative-side carrier amplifier (second amplifier) and the reference voltage V_{ref1}. The DC elimination unit 1320e forms a differential amplifier circuit that includes a transistor Q61 (first transistor) and a transistor Q63 (second transistor). A base or a gate of the transistor Q61 (first transistor) is electrically connected to the output terminal 1311c of the comparing part 1311 (first comparing part), and a signal obtained by eliminating a DC component of the second output signal is output through a collector or a drain of the transistor Q61. A base or a gate of the transistor Q63 (second transistor) is electrically connected to the output terminal 1312c of the comparing part 1312 (second comparing part), and a signal obtained by eliminating a DC component of the third output signal is output through a collector or a drain of the transistor Q63. The detection unit 1330 includes a detection part 1331 (first detection part) whose input terminal is electrically connected to the collector or the drain of the transistor Q61 (first transistor), a first control signal corresponding to the signal level of the signal output from the positive-side carrier amplifier (first amplifier) being output through an output terminal of the detection unit 1330, and a detection part 1332 (second detection part) whose input terminal is electrically connected to the collector or the drain of the transistor Q63 (second transistor), a second control signal corresponding to the signal level of the signal output from the negative-side carrier amplifier (second amplifier) being output through an output terminal of the detection part 1332. Accordingly, the detection circuit 1300e can output an appropriate signal for detecting saturation of the carrier amplifier 1100 to the detection unit 1330.

<17> The detection circuit according to <16>, as a detection circuit 1300f of the power amplifier module 1000 according to an illustrative embodiment of the present disclosure, further includes a capacitor C71 (first capacitor) that is connected in series between a base or a gate of a transistor Q71 (first transistor) and the output terminal 1311c of the comparing part 1311 (first comparing part), and a capacitor C72 (second capacitor) that is connected in series between a base or a gate of a transistor Q72 (second transistor) and the output terminal 1312c of the comparing part 1312 (second comparing part). Accordingly, in the detection circuit 1300f, a situation in which an output from the comparing unit 1310 flows into a bias circuit for a differential amplifier circuit 1320f and a bias point of the differential amplifier circuit 1320f is thus changed can be prevented.

<18> The detection circuit according to <17>, as the detection circuit 1300f of the power amplifier module 1000 according to an illustrative embodiment of the present disclosure, further includes a bias circuit (for example, a circuit including transistors Q81 and Q82 and the reference voltage V_{ref1} illustrated in FIG. 17) that supplies a bias to a node N1 between the output terminal 1311c of the comparing part 1311 (first comparing part) and the capacitor C71 (first capacitor) and supplies a bias to a node N2 between the output terminal 1312c of the comparing part 1312 (second comparing part) and the capacitor C72 (second capacitor). In the detection circuit 1300f, due to division of the bias circuit, a situation in which an output from the comparing unit 1310 flows into the bias circuit for the differential amplifier circuit 1320f and the bias point of the differential amplifier circuit 1320f is thus changed can be prevented.

<19> The detection circuit according to any one of <1> to <18>, as a detection circuit 1300g of the power amplifier module 1000 according to an illustrative embodiment of the present disclosure, further includes a transistor Q90 whose base or gate is electrically connected to the output terminal (emitters of transistors Q31 and Q32 illustrated in FIG. 18) of the detection unit 1330, whose emitter or source is connected to a ground with a resistor R90 (resistor element) interposed therebetween, and whose collector or drain is electrically connected to a detection terminal 1302 for outputting the control signal D_{cont}. Accordingly, since the control signal D_{cont} can be set to have an appropriate signal level, the detection circuit 1300g can properly detect saturation of the carrier amplifier 1100 (amplifier in the final stage).

<20> The detection circuit according to any one of <1> to <19>, as the detection circuit 1300g of the power amplifier module 1000 according to an illustrative embodiment of the present disclosure, is a detection circuit that is formed on a semiconductor substrate. In a case where a distance between a center part Pce1 of a plurality of transistors forming the predetermined amplifier (for example, a positive-side carrier amplifier and a negative-side carrier amplifier) and a reference voltage transistor Tv as a transistor that generates a reference voltage Vref is represented by D1 and a distance between the center part Pce1 and a current source transistor Ti as a transistor that configures a current source that is connected in series between an emitter or a source of the detection unit 1330 and a ground is represented by D2, Expression (1) described below is satisfied. Accordingly, since the temperature of the current source transistor Ti and the temperature of the reference voltage transistor Tv change in a similar manner, the control signal D_{cont} output from the detection terminal 1302 is stable.

$$( Math . 2 )$$

$$\vert D 1 - D 2 \vert / ( D 1 + D 2 ) < 1 \qquad ( 1 )$$

<21> In the detection circuit 1300h of the power amplifier module 1000 according to an illustrative embodiment of the present disclosure, the comparing part 1311 (first comparing part) includes a transistor Q11a (third transistor) whose collector or drain is electrically connected to an input terminal 1311a of the comparing part 1311 (first comparing part) to which the signal output from the positive-side carrier amplifier (first amplifier) is input, whose emitter or source is electrically connected to a ground, and whose base or gate is electrically connected to the transistor Q51 (third amplifier). The comparing part 1312 (second comparing part) includes a transistor Q12a (fourth transistor) whose collector or drain is electrically connected to an input terminal 1312a of the comparing part 1312 (second comparing part) to which the signal output from the negative-side carrier amplifier (second amplifier) is input, whose emitter or source is electrically connected to the ground, and whose base or gate is electrically connected to the transistor Q52 (fourth amplifier). The transistor Q11a (third transistor) is provided, in plan view, inside a region R surrounded by a ground wire GLN that is electrically connected to a ground layer GND. The input terminal 1311a of the comparing part 1311 (first comparing part) is provided outside the region R surrounded by the ground wire GLN. The transistor Q12a (fourth transistor) is provided, in plan view, inside the region R surrounded by the ground wire GLN that is electrically connected to the ground layer GND. The input terminal 1312a of the comparing part 1312 (second comparing part) is provided outside the region R surrounded by the ground wire GLN. Accordingly, the power amplifier module 1000 prevents an erroneous operation of the detection circuit 1300h.

<22> In the detection circuit 1300h of the power amplifier module 1000 according to an illustrative embodiment of the present disclosure, the collector or the drain of the transistor Q11a (third transistor) is electrically connected to the input terminal 1311a of the comparing part 1311 (first comparing part) by a first wire LN1. The transistor Q11a (third transistor) is provided in such a manner that a length L1, in plan view, of a part of the first wire LN1 that is inside the region R surrounded by the ground wire GLN and including the transistor Q11a (third transistor) is shorter than a length L2, in plan view, of a part of the first wire LN1 that is outside the region R. The collector or the drain of the transistor Q12a (fourth transistor) is electrically connected to the input terminal 1312a of the comparing part 1312 (second comparing part) by a second wire LN2. The transistor Q12a (fourth transistor) is provided in such a manner that a length, in plan view, of a part of the second wire LN2 that is inside the region R surrounded by the ground wire GLN and including the transistor Q12a (fourth transistor) is shorter than a length, in plan view, of a part of the second wire LN2 that is outside the region R. Accordingly, the power amplifier module 1000 can prevent an erroneous operation of the detection circuit 1300h more reliably.

<23> The detection circuit 1300h of the power amplifier module 1000 according to an illustrative embodiment of the present disclosure includes an amplifier 1360 (fifth amplifier) whose input terminal is electrically connected to the output terminal of the comparing unit 1310, a DC elimination unit 1370 (intermediate-stage DC elimination unit) whose first terminal is electrically connected to an output terminal of the amplifier 1360 (fifth amplifier), the signal obtained by eliminating the DC component of the first output signal being output through a second terminal of the DC elimination unit 1370, an amplifier 1340 (sixth amplifier) whose input terminal is electrically connected to the second terminal of the DC elimination unit 1370 (intermediate-stage DC elimination unit) and whose output terminal is electrically connected to the first terminal of the DC elimination unit 1320, and a feedback circuit 1380 that electrically connects the output terminal of the amplifier 1340 (sixth amplifier) to the input terminal of the amplifier 1360 (fifth amplifier) and feeds a signal obtained by amplifying, at the amplifier 1340 (sixth amplifier), the signal obtained by eliminating the DC component of the first output signal back to the amplifier 1360 (fifth amplifier). Accordingly, in the detection circuit 1300h, detection sensitivity can be improved by the amplifier 1360, and the same time, temperature dependency of the current amplification factor of the amplifiers 1340 and 1360 can be suppressed by the feedback circuit 1380.

<24> The detection circuit 1300h of the power amplifier module 1000 according to an illustrative embodiment of the present disclosure includes a transistor Q91 (seventh amplifier) whose input terminal (in this example, an emitter of the transistor Q91) is electrically connected to the output terminal of the comparing part 1311 (first comparing part), a DC elimination part 1371 (first intermediate-stage DC elimination part) whose first terminal is electrically connected to an output terminal of the transistor Q91 (seventh amplifier), a signal obtained by eliminating a DC component being output through a second terminal of the DC elimination part 1371, a transistor Q92 (eighth amplifier) whose input terminal (in this example, an emitter of the transistor Q92) is electrically connected to the output terminal of the comparing part 1312 (second comparing part), and a DC elimination part 1372 (second intermediate-stage DC elimination part) whose first terminal is electrically connected to an output terminal of the transistor Q92 (eighth amplifier), a signal obtained by eliminating a DC component being output through a second terminal of the DC elimination part 1372. The comparing part 1311 (first comparing part) includes a transistor Q11a (fifth transistor) whose collector or drain is electrically connected to the input terminal of the comparing part 1311 (first comparing part) to which the signal output from the positive-side carrier amplifier (first amplifier) is input and whose emitter or source is electrically connected to a ground. The comparing part 1312 (second comparing part) includes a transistor Q12a (sixth transistor) whose collector or drain is electrically connected to the input terminal 1312a of the comparing part 1312 (second comparing part) to which the signal output from the negative-side carrier amplifier (second amplifier) is input and whose emitter or source is electrically connected to the ground. The transistor Q91 (seventh amplifier) whose collector or drain is connected in series to a capacitor C73 (first capacitor) of the DC elimination part 1371 (first intermediate-stage DC elimination part), whose base or gate is supplied with the reference voltage and is electrically connected to the ground with a predetermined transistor Q93 interposed therebetween, and whose emitter or source is electrically connected to the base or the gate of the transistor Q11a (fifth transistor) so that the reference voltage is supplied to the base or the gate of the transistor Q11a (fifth transistor). The transistor Q92 (eighth amplifier) whose collector or drain is connected in series to a capacitor C74 (second capacitor) of the DC elimination part 1372 (second intermediate-stage DC elimination part), whose base or gate is supplied with the reference voltage and is electrically connected to the ground with a predetermined transistor Q94 interposed therebetween, and whose emitter or source is electrically connected to the base or the gate of the transistor Q12a (sixth transistor) so that the reference voltage is supplied to the base or the gate of the transistor Q12a (sixth transistor). Accordingly, in the detection circuit 1300h, since a single transistor (in this example, each of the transistors Q91 and Q92) is used for bias supply and signal amplification, the size of the circuit can be reduced.

<25> In the detection circuit 1300h of the power amplifier module 1000 according to an illustrative embodiment of the present disclosure, the detection unit 1330 includes a detection part 1331 (first detection part) and a detection part 1332 (second detection part). The detection part 1331 (first detection part) includes a transistor Q31 whose base or gate is electrically connected to a second terminal of a capacitor C21 (first DC elimination part) and whose emitter or source is electrically connected to a ground, a first control signal being output through a collector or a drain of the transistor Q31. The detection part 1332 (second detection part) includes a transistor Q32 whose base or gate is electrically connected to a second terminal of a capacitor C22 (second DC elimination part) and whose emitter or source is electrically connected to the ground, a second control signal being output through a collector or a drain of the transistor Q32. The first control signal and the second control signal are combined together and the control signal D_{cont} is output through the output terminal of the detection unit. Accordingly, in the power amplifier module 1000, the size of a filter circuit (not illustrated in the drawing) connected to the detection terminal 1302 can be reduced.

The embodiments described above are intended to facilitate understanding of the present disclosure and are not to be interpreted as limiting the present disclosure. The present disclosure can be modified or improved without necessarily departing from the gist of the disclosure, and the present disclosure encompasses equivalents thereof. That is, design changes appropriately added to the embodiments by those skilled in the art are also included in the scope of the present disclosure as long as the design changes include features of the present disclosure. For example, elements included in each of the embodiments and arrangement of the elements are not limited to those illustrated above and can be modified appropriately.

### REFERENCE SIGNS LIST

1000 . . . power amplifier module, 1100 . . . carrier amplifier, 1200 . . . peak amplifier, 1300 . . . detection circuit, 1400 . . . splitter, 1500 . . . combiner.

1. A detection circuit comprising:
a comparing portion configured to output, through an output terminal of the comparing portion, a first output signal corresponding to a difference between a signal level of a signal output from a predetermined amplifier and a reference voltage;
a DC elimination portion whose first terminal is electrically connected to the output terminal of the comparing portion, a signal obtained by eliminating a DC component of the first output signal being output through a second terminal of the DC elimination portion; and
a detection portion whose input terminal is electrically connected to the second terminal of the DC elimination portion, a control signal corresponding to the signal level of the signal output from the predetermined amplifier being output through an output terminal of the detection portion.

2. The detection circuit according to claim 1, wherein the DC elimination portion comprises a capacitor in which the first terminal of the DC elimination portion is electrically connected to the output terminal of the comparing portion and the signal obtained by eliminating the DC component of the first output signal is output through the second terminal of the DC elimination portion.

3. The detection circuit according to claim 1, wherein the comparing portion comprises a transistor whose emitter or source is electrically connected to an output terminal of the predetermined amplifier, whose base or gate is electrically connected to the reference voltage, and whose collector or drain is electrically connected to the first terminal of the DC elimination portion.

4. The detection circuit according to claim 1, wherein the comparing portion comprises a transistor whose emitter or source is electrically connected to ground, whose collector or drain is electrically connected to an output terminal of the predetermined amplifier, and whose base or gate is electrically connected to the reference voltage and electrically connected to the first terminal of the DC elimination portion.

5. The detection circuit according to claim 1, wherein the detection portion comprises a transistor whose base or gate is electrically connected to the second terminal of the DC elimination portion and whose collector or drain is electrically connected to a power source, the control signal being output through an emitter or a source of the transistor.

6. The detection circuit according to claim 1,
wherein the predetermined amplifier is a differential amplifier that comprises a first amplifier and a second amplifier,
wherein the comparing portion comprises:
a first comparing part that receives a signal output from an output terminal of the first amplifier and the reference voltage and that is configured to output, through a first output terminal of the first comparing part, a second output signal corresponding to a difference between a signal level of the signal output from the first amplifier and the reference voltage, and
a second comparing part that receives a signal output from an output terminal of the second amplifier and the reference voltage and that is configured to output, through a second output terminal of the second comparing part, a third output signal corresponding to a difference between a signal level of the signal output from the second amplifier and the reference voltage,
wherein the DC elimination portion comprises:
a first DC elimination part whose first terminal is electrically connected to the first output terminal of the first comparing part, a signal obtained by eliminating a DC component of the second output signal being output through a second terminal of the first DC elimination part, and
a second DC elimination part whose first terminal is electrically connected to the second output terminal of the second comparing part, a signal obtained by eliminating a DC component of the third output signal being output through a second terminal of the second DC elimination part, and
wherein the detection portion comprises:
a first detection part whose input terminal is electrically connected to the second terminal of the first DC elimination part, a first control signal corresponding to the signal level of the signal output from the first amplifier being output through an output terminal of the first detection part, and
a second detection part whose input terminal is electrically connected to the second terminal of the second DC elimination part, a second control signal corresponding to the signal level of the signal output from the second amplifier being output through an output terminal of the second detection part.

7. The detection circuit according to claim 1,
wherein the predetermined amplifier is a differential amplifier that comprises a first amplifier and a second amplifier,
wherein the comparing portion comprises:
a first comparing part that receives a signal output from an output terminal of the first amplifier and the reference voltage and that is configured to output, through a first output terminal of the first comparing part, a second output signal corresponding to a difference between a signal level of the signal output from the first amplifier and the reference voltage, and
a second comparing part that receives a signal output from an output terminal of the second amplifier and the reference voltage and that is configured to output, through a second output terminal of the second comparing part, a third output signal corresponding to a difference between a signal level of the signal output from the second amplifier and the reference voltage,
wherein the DC elimination portion comprises:
a transformer that has a pair of input terminals and a pair of output terminals,
a first input terminal of the pair of input terminals being electrically connected to the output terminal of the first comparing part, a second input terminal of the pair of input terminals being electrically connected to the output terminal of the second comparing part, and
wherein the detection portion comprises:
a first detection part whose input terminal is electrically connected to a first output terminal of the DC elimination portion, a first control signal corresponding to the signal level of the signal output from the first amplifier being output through an output terminal of the first detection part, and
a second detection part whose input terminal is electrically connected to a second output terminal of the DC elimination portion, a second control signal corresponding to the signal level of the signal output from the second amplifier being output through an output terminal of the second detection part.

8. The detection circuit according to claim 6, further comprising at least one of:
a first variable current source that is electrically connected to the input terminal of the first detection part and that is configured to adjust a first current, and
a second variable current source that is electrically connected to the input terminal of the second detection part and that is configured to adjust a second current.

9. The detection circuit according to claim 6, further comprising:
a first capacitor whose first end is electrically connected to an input terminal of the first comparing part and whose second end is electrically connected to the output terminal of the second comparing part; and
a second capacitor whose first end is electrically connected to an input terminal of the second comparing part and whose second end is electrically connected to the output terminal of the first comparing part.

10. The detection circuit according to claim 1, further comprising:
an amplifier whose input terminal is electrically connected to the second terminal of the DC elimination portion and whose output terminal is electrically connected to the input terminal of the detection portion.

11. The detection circuit according to claim 6, further comprising:
a third amplifier whose input terminal is electrically connected to the second terminal of the first DC elimination part and whose output terminal is electrically connected to the input terminal of the first detection part; and
a fourth amplifier whose input terminal is electrically connected to the second terminal of the second DC elimination part and whose output terminal is electrically connected to the input terminal of the second detection part.

12. The detection circuit according to claim 7, further comprising:
a third amplifier whose input terminal is electrically connected to the first output terminal of the DC elimination portion and whose output terminal is electrically connected to the input terminal of the first detection part; and
a fourth amplifier whose input terminal is electrically connected to the second output terminal of the DC elimination portion and whose output terminal is electrically connected to the input terminal of the second detection part.

13. The detection circuit according to claim 1, further comprising:
an amplifier whose input terminal is electrically connected to the output terminal of the comparing portion and whose output terminal is electrically connected to the first terminal of the DC elimination portion.

14. The detection circuit according to claim 6, further comprising:
a third amplifier whose input terminal is electrically connected to the output terminal of the first comparing part and whose output terminal is electrically connected to the first terminal of the first DC elimination part; and
a fourth amplifier whose input terminal is electrically connected to the output terminal of the second comparing part and whose output terminal is electrically connected to the first terminal of the second DC elimination part.

15. The detection circuit according to claim 7, further comprising:
a third amplifier whose input terminal is electrically connected to the output terminal of the first comparing part and whose output terminal is electrically connected to the first input terminal of the DC elimination portion; and
a fourth amplifier whose input terminal is electrically connected to the output terminal of the second comparing part and whose output terminal is electrically connected to the second input terminal of the DC elimination portion.

16. The detection circuit according to claim 1,
wherein the predetermined amplifier is a differential amplifier that comprises a first amplifier and a second amplifier,
wherein the comparing portion comprises:
a first comparing part that receives a signal output from an output terminal of the first amplifier and the reference voltage and that is configured to output, through a first output terminal of the first comparing part, a second output signal corresponding to a difference between a signal level of the signal output from the first amplifier and the reference voltage, and
a second comparing part that receives a signal output from an output terminal of the second amplifier and the reference voltage and that is configured to output, through a second output terminal of the second comparing part, a third output signal corresponding to a difference between a signal level of the signal output from the second amplifier and the reference voltage,
wherein the DC elimination portion forms a differential amplifier circuit that comprises a first transistor and a second transistor,
wherein a base or a gate of the first transistor is electrically connected to the output terminal of the first comparing part, and a signal obtained by eliminating a DC component of the second output signal is output through a collector or a drain of the first transistor,
wherein a base or a gate of the second transistor is electrically connected to the output terminal of the second comparing part, and a signal obtained by eliminating a DC component of the third output signal is output through a collector or a drain of the second transistor, and
wherein the detection portion comprises:
a first detection part whose input terminal is electrically connected to the collector or the drain of the first transistor, a first control signal corresponding to the signal level of the signal output from the first amplifier being output through an output terminal of the first detection part, and
a second detection part whose input terminal is electrically connected to the collector or the drain of the second transistor, a second control signal corresponding to the signal level of the signal output from the second amplifier being output through an output terminal of the second detection part.

17. The detection circuit according to claim 16, further comprising:
a first capacitor that is connected in series between the base or the gate of the first transistor and the output terminal of the first comparing part; and
a second capacitor that is connected in series between the base or the gate of the second transistor and the output terminal of the second comparing part.

18. The detection circuit according to claim 17, further comprising:
a bias circuit that configured to supply a first bias to a node between the output terminal of the first comparing part and the first capacitor, and to supply a second bias to a node between the output terminal of the second comparing part and the second capacitor.

19. The detection circuit according to claim 1, further comprising:
a transistor whose base or gate is electrically connected to the output terminal of the detection portion, whose emitter or source is connected to ground with a resistor element interposed therebetween, and whose collector or drain is electrically connected to a detection terminal for outputting the control signal.

20. The detection circuit according to claim 5,
wherein the detection circuit is formed on a semiconductor substrate, and
wherein |D1−D2|/(D1+D2)<1,
where D1 is a distance between a center part of a plurality of transistors forming the predetermined amplifier and a reference voltage transistor that generates the reference voltage, and
where D2 is a distance between the center part and a transistor of a current source connected in series between the emitter or the source of the transistor of the detection portion and ground.
